(19) United States
(12) Patent Application Publication
(10) Pub. No.: US 2025/0216449 A1
(43) Pub. Date: Jul. 3, 2025

(54) INTEGRATED CIRCUIT TESTING STRUCTURE FOR PAD BOND MISALIGNMENT DETECTION AND MEASUREMENT

(71) Applicant: Intel Corporation, Santa Clara, CA (US)

(72) Inventors: Jagat Shakya, Hillsboro, OR (US); Ankit Singh, Hillsboro, OR (US); Ethan Caughey, Portland, OR (US); Joseph Parks, Portland, OR (US)

(73) Assignee: Intel Corporation, Santa Clara, CA (US)

(21) Appl. No.: 18/400,929

(22) Filed: Dec. 29, 2023

(51) Int. Cl. G01R 31/28

(52) U.S. Cl. CPC G01R 31/2896

(57) ABSTRACT

An integrated circuit (IC) package comprises a stack with first and second electronic devices respectively having a first array and a second array of rows and columns of pads bonded to each other. At least one testing structure comprises a first pattern of first pads of the first array, a second pattern of second pads of the second array, and at least four pad-pairs of one of the first pads adjacent to one of the second pads, wherein each pair has different pads than the other pairs. An aligned state of the first and second electronic devices exists wherein each pad-pair has a different offset length separating the first pad from the second pad, and wherein none of the first and second pads of the pairs are electrically connected.

### BACKGROUND

In electronics manufacturing, integrated circuit (IC) packaging involves bonding an integrated circuit (IC) die diced from a wafer onto another component in the package such as another die still on a wafer (or target wafer) or other package component. Conventional optical imaging alignment systems use fiducials (or fiducial marks) that are detectable on the die to accurately align and bond the conductive pads on the die with corresponding pads on the other component, die, and/or wafer. After the die has been bonded, conventional post-bond alignment testing is performed with fiducials to detect, reject, and/or discard packages with pad misalignments to avoid high yield losses and low quality, unreliable final products. Fiducials, however, often require keep out zones (KOZs) where no metallization is permitted over the fiducial on the dies in order to prevent metallization from blocking a view of the fiducials for imaging equipment. Thus, avoidance of the fiducials for post-bond alignment testing is desired.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a schematic diagram of an X-Y view of an integrated circuit (IC) die with a conductive pad array according to at least one of the implementations herein;

FIG. 2 is a schematic diagram of an X-Y view of stacked dies where one die translated relative to the other die according to at least one of the implementations herein;

FIG. 3 is a schematic diagram of an X-Y view of stacked dies where one die rotated relative to the other die according to at least one of the implementations herein;

FIG. 4 is a schematic diagram of an X-Y view of an IC die with a conductive pad array and a base testing pattern of base pads according to at least one of the implementations herein;

FIG. 5 is a schematic diagram of an X-Y view of an IC die with a conductive pad array and a probing pattern of probe pads according to at least one of the implementations herein;

FIG. 6 is a schematic diagram of an X-Y see-through view of a pad alignment testing structure with a pad testing pattern with two stacked IC dies with the base pads of FIG. 4 aligned with the probe pads of FIG. 5 according to at least one of the implementations herein;

FIG. 7 is a schematic diagram of an X-Y see-through view of an alternative pad alignment testing pattern according to at least one of the implementations herein;

FIG. 8A is a schematic diagram of an X-Z cross-sectional side view of a testing structure at two ideally aligned die according to at least one of the implementations herein;

FIG. 8B is a schematic diagram of an X-Z cross-sectional side view of a testing structure of the two die of FIG. 8A mis-aligned according to at least one of the implementations herein;

FIGS. 9A-9D are schematic diagrams of close-up cross-sectional views of a testing structure showing different ideal-die alignment pad offset positions according to at least one of the implementations herein;

FIG. 10 is a schematic diagram of an X-Y upper view of two stacked IC dies with multiple testing structures according to at least one of the implementations herein;

FIGS. 11A-11D are schematic diagrams of close-up X-Y views of testing structures on the two stacked die of FIG. 10 with ideal alignment according to at least one of the implementations herein;

FIGS. 12A-12D are schematic diagrams of close-up X-Y views of the testing structures of FIG. 10 when two stacked die are in misalignment by a translation according to at least one of the implementations herein;

FIGS. 13A-13D are schematic diagrams of close-up X-Y views of the testing structures of FIG. 10 when two stacked die are in misalignment by a translation and rotation according to at least one of the implementations herein;

FIG. 14 is a schematic diagram of a cross-sectional view and circuit diagram of a pad alignment testing structure and showing stacked devices in alignment according to at least one of the implementations herein;

FIG. 15 is a schematic diagram of a cross-sectional view and circuit diagram of a pad alignment testing structure and showing stacked devices in misalignment according to at least one of the implementations herein;

FIG. 16 is a schematic diagram of a system for testing pad alignment on a stack of IC devices according to at least one of the implementations herein;

FIG. 17 is a flow chart of an example method of detecting and measuring misalignment between probe and base pads of stacked IC devices according to at least one of the implementations herein;

FIG. 18 is an arrangement map for a table provided by FIGS. 19A-19F;

FIGS. 19A-19F is a table showing signal codes for various alignments between probe pads and base pads of two stacked IC devices according to at least one of the implementations herein;

FIG. 20 is a functional block diagram of an electronic computing device according to at least one of the implementations herein; and

FIG. 21 illustrates a mobile computing platform and a data server machine employing an IC device comprising one or more IC dies with pad alignment testing structures according to at least one of the implementations herein.

### DETAILED DESCRIPTION

Implementations are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary implementations. Further, it is to be understood that other implementations may be utilized and structural and/or functional changes may be made without departing from the scope of claimed subject matter. It should also be noted that directions and references (e.g., up, down, top, bottom, etc.) may be used merely to facilitate the description of features in the drawings and relationship between the features. Therefore, the following detailed description is not to be taken in a limiting sense and the scope of claimed subject matter is defined solely by the appended claims and their equivalents.

In the following description, numerous details are set forth. However, it will be apparent to one skilled in the art, that implementations may be practiced without these specific details. In some instances, well-known methods and devices are shown in block diagram form, rather than in detail, to avoid obscuring the implementations. Reference throughout this specification to “an implementation” or “one implementation” or “some implementations” refers to a particular feature, structure, function, or characteristic described in connection with the implementation that is included in at least one implementation. Thus, the appearances of the phrase “in an implementation” or “in one implementation” or “some implementations” in various places throughout this specification are not necessarily referring to the same implementation. Furthermore, the particular features, structures, functions, or characteristics may be combined in any suitable manner in one or more implementations. For example, a first implementation may be combined with a second implementation anywhere the particular features, structures, functions, or characteristics associated with each of the two implementations are not mutually exclusive.

As used in the description and the appended claims, the singular forms “a”, “an” and “the” are intended to include the plural forms as well, unless the context clearly indicates otherwise. It also will be understood that the term “and/or” as used herein refers to and encompasses any single associated listed item and any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular implementations, “connected” may be used to indicate that two or more elements are in direct physical, optical, or electrical contact with each other. “Coupled” may be used to indicated that two or more elements are in either direct or indirect (with other intervening elements between them) physical, optical, or electrical contact with each other, and/or that the two or more elements co-operate or interact with each other (e.g., as in a cause and effect relationship).

The terms “over,” “under,” “between,” and “on” as used herein refer to a relative position of one component or material with respect to other components or materials where such physical relationships are noteworthy. For example, in the context of materials, one material or structure disposed over or under another may be directly in contact or may have one or more intervening materials. Moreover, one material disposed between two materials may be directly in contact with the two materials or may have one or more intervening materials. In contrast, a first material or structure “on” a second material or structure is in direct contact with that second material/structure. Similar distinctions are to be made in the context of component assemblies where a first component may be “on” or “over” a second component.

As used throughout this description, and in the claims, a list of items joined by the term “at least one of” or “one or more of” can refer to any combination of the listed terms. For example, the phrase “at least one of A, B, or C” can refer to A; B; C; A and B; A and C; B and C; or A, B, and C.

In the manufacture of IC devices, one or more “device layers” are fabricated during front-end-of-line (FEOL) processing. Device layers include active or passive devices, or devices of both types. In some implementations, the active devices are field effect transistors (FETs). Active and passive devices in a device layer are examples of “metallization features.” In addition, one or more “metallization layers” are fabricated during back-end-of line (BEOL) processing. Active and passive devices of a device layer are interconnected into circuitry with metal structures within one or more metallization layers. A metallization layer may comprise any number of metal structures separated by inter-layer dielectric (ILD) material. The metal structures in a metallization layer are more examples of “metallization features,”

In electronics manufacturing, IC packaging is a stage of the manufacturing process where an IC, that has been fabricated on a die or chip comprising a semiconducting material, is coupled to a supporting case or “package” that can protect the IC from physical damage and support electrical contacts suitable for further connecting to another IC die, a package substrate, and/or a host component, such as a printed circuit board (PCB). In the IC industry, the process of fabricating a package is often referred to as packaging, or assembly.

The IC industry is continually striving to produce higher computational performance in smaller packages for use in various electronic products, such as computer servers, portable computers, electronic tablets, desktop computers, and mobile communication handsets. High performance computing products often now include one or more microelectronic packages that contain various combinations of semiconductor tiles, chips, chiplets, and dies that are integrated into one functional unit. These composite, or heterogeneous, IC device structures may include tiles, chips, chiplets, or dies created using diverse technologies and materials. The tiles, chips, chiplets, or dies may be stacked vertically, placed horizontally, or both. Connections between different devices may employ a variety of technologies, including direct bonding. Chiplets, rather than monolithic dies, disaggregate the circuits. The chiplets are electrically coupled by interconnect bridges. Thus, for example, 3D die assembly allows for die disaggregation which provides flexibility of assembling different chiplets from multiple sources and multiple technologies on a same base die. The term “chiplet” is used herein to refer to a die that is part of an assembly of interconnected dies forming a complete IC in terms of application and/or functionality, such as a memory chip, microprocessor, microcontroller, commodity IC (e.g., chip used for repetitive processing routines, simple tasks, application specific IC, etc.), and system-on-a-chip (SoC). In other words, the chiplets are individual dies (or IC dies) connected together to create the functionalities of a monolithic IC. By using separate chiplets, each individual chiplet can be designed and manufactured optimally for a particular functionality. For example, a processor core that contains logic circuits might aim for performance, and thus might require a very speed-optimized layout. This has different manufacturing requirements compared to a USB controller, which is built to meet certain USB standards, rather than for processing speed. Thus, by having different parts of the overall design separated into different chiplets, each one optimized in terms of design and manufacturing, the overall yield and cost of the combined chiplet solution may be improved.

The connectivity between these chiplets is achievable by many different ways. For example, in 2.5D packaging solutions, a silicon interposer and Through Silicon Vias (TSVs) connect dies at silicon interconnect speed in a minimal footprint. In another example, called Embedded Multi-Die Interconnect Bridge (EMIB), a silicon bridge embedded under the edges of two interconnecting dies facilitates electrical coupling between them. In a three-dimensional (3D) architecture, the chiplets are stacked one above the other, creating a smaller footprint overall. Typically, the electrical connectivity and mechanical coupling in such 3D architecture is achieved using TSVs and high pitch solder-based bumps (e.g., C2 interconnections). The EMIB and the 3D stacked architecture may also be combined using an omni-directional interconnect (ODI), which allows for top-packaged chips to communicate with other chips horizontally using EMIB and vertically, using Through Mold Vias (TMVs) which are typically larger than TSVs.

In some implementations that use chiplets, a composite chip may have a fill dielectric layer over BEOL in a metallization stack. A fill dielectric layer may fully surround chiplet sidewalls, embedding a chiplet within dielectric material. A fill dielectric may stabilize and strengthen a composite die structure, and/or provide a platform for higher BEOL metallization layers. In some implementations, a fill dielectric layer comprises an inorganic dielectric material, such as, but not limited to, amorphous and polycrystalline silicon oxides, in some cases having a higher k than ILD materials. In some other implementations, a fill dielectric layer comprises an organic material, such as, but not limited to, epoxy resins and epoxy resin composites. Vias may extend through a fill dielectric layer. Vias also may interconnect upper BEOL metallization levels or embedded devices to a level M₄ and lower metallization levels. Vias may route power and/or signals to device layer. The IC dies or electronic devices discussed below can be chiplets, may have one or more chiplets, or may be coupled to, or on, one or more chiplets.

A variety of manufacturing challenges exist at the IC packaging stage of electronics manufacturing. Some manufacturing challenges arise when an IC die is stacked vertically on, or placed horizontally with, another IC die in an IC package. The IC package examples described herein may be manufactured, in part, with bonding techniques in which metal features such as conductive pads surrounded by an insulator of one IC die are directly fused to metal features surrounded by an insulator of another die. When both the metal features and the insulators are fused, the resultant composite structure comprises a hybrid bonded interface of both metallurgically inter-diffused metals and chemically bonded insulators. Prior to bonding, each IC die may be fabricated in a monolithic process separate from that of the other IC die. As such, an IC die may utilize the same or different semiconductor device fabrication technologies as the IC die to which it is bonded. These bonding techniques may be referred to as “hybrid” or “direct” bonding where the bonded metal form hybrid bonding interconnects (HBIs) that avoid the use of solder balls. Herein, “hybrid direct bonds” may comprise die-to-die (DTD) interconnects with sub 10 micrometer pitch. In other words, the separation between any two hybrid direct bonds, and in turn the conductive pads of the array, is less than or equal to 10 micrometers.

The direct bonding enables tighter pitches between interconnects on the surface of an IC die than the pitches used in traditional copper to copper bonding methods with solder. For example, pitches may be as small as 1-3 micrometers while the conductive pad width may be 200-500 nm with a margin of error at three sigma.

Failure to accurately align the electrically conductive pads that cooperatively form an interconnect on the IC die, however, can result in a pad on a die (or wafer) with insufficient contact with a corresponding pad of another die (or wafer), resulting in a device that does not operate correctly or at all. In addition, even a device that passes through testing but has misaligned pads that are initially slightly touching but not in sufficient contact with each other still will be unreliable because the device will fail early due to chemical copper consumption over time that causes disengagement between the misaligned two pads early due to the smaller surface areas of contact between the misaligned pads.

Accordingly, the tighter die pitch used in direct bonding can require significantly higher placement accuracy during bonding operations as compared with traditional bonding methods. This may be referred to as pre-bond overlay measurement performed by using microscopic light-based optical (visible light wavelength) cameras to perform the alignment during pre-bonding. This often involves aligning top and bottom pads using optical alignment marks or fiducials on each of the dies being bonded together.

A post-bond inspection also may be performed to reject resulting bonded devices with misaligned pads. Significant or gross misalignment from pad to corresponding pad in the range of half the pitch (pad to pad distance) or more results in massive electrical failure and should be easily detected at electrical sort or etest stages. As the bond pad pitch reduces to 1 micron and less to submicron level, however, misalignment that is smaller than half the pitch is detected by using optical monitoring devices and then manual inspection of the captured images. Specifically, conventional failure analysis (FA) and/or 3D X-ray techniques may be used to determine the extent of a misalignment.

Typically, the integrated circuit manufacturing involves aligning and bonding two stacked IC dies (D2D), die to wafer (D2 W), or wafer to wafer (W2 W) when the die is still on a wafer. Failure analysis with imaging is used since bulk silicon is transparent at various wavelengths used in near infrared (NIR) imaging for example. As long as keep out zones (KOZ) are used so that metallization does not block the view of the fiducials, FA can be used after the two bonded layers are stacked with each other. Otherwise, 3D x-ray techniques may be used that capture an x-ray image of the bonded pads.

However, the use of the FA and X-ray techniques require the use of expensive equipment. Also, the manual inspections of the images with fiducials or x-rays as well as the setup of these systems consume a lot of time (such processes typically cannot be performed “on the fly” and require a lot of setup of equipment to direct and focus x-ray and IR cameras on a target die stack for example) and human resources. Thus, when the tests are skipped due to efficiency or due to human or other error, the misalignments may go unnoticed to be discovered only after the assembly of the packaging holding the misaligned dies is deployed to end users, which can result in enormous yield losses and/or reliability issues as mentioned above.

Also, in die to wafer (or wafer to wafer) bonding, each die may have a different amount of translational and rotational misalignment. Thus, detection of the misalignment per die itself also consumes significant amounts of time and expense to perform a 3D x-ray and FA analysis on a wafer scale.

As yet another issue, the imaging techniques require the KOZs above fiducials and which occupies volume on an IC device that could have been used for functional metallization instead, thereby wasting these volumes.

To resolve these issues, the present system and methods disclose pad alignment test (or testing) structures, which may be dedicated test (or testing) structures, and an array of pads on each of two electronic devices, such as two dies (D2D), a die and wafer (D2 W), or two wafers (W2 W), bonded to each other pad to pad, and in one form, in hybrid bonding. The test structure may have multiple grounded (or base pads) on a first die with a first array, and multiple test or probe (or probing or monitoring) pads on a second array of a second die. The base pads and the test pads may be arranged in a merged pattern so that offset distances between the base pads and the test pads vary from pair to pair of corresponding (or adjacent) base pad and test pad. By one form, while the base pads are all grounded on one of the die (or wafers), the test or probe pads on the other die (or wafer) may be coupled to external testing equipment with circuitry that provides electricity to the probe pads. The testing equipment, unit (such as Automated Test Equipment (ATE)), or other testbench can detect a short circuit (or leakage) when a probe pad has contact with a base pad (or is extremely close to the base pad). This indicates a misalignment of the two arrays or parts of the two arrays that are bonded together. Each pair of base and probe pads with a different offset have a unique location in the merged pattern, and depending on the varying offset distances between base and probe pads. Thus, the detection of a leakage signal corresponding to any pad or group of pads can be used to determine the direction of the misalignment as well as magnitude (within a certain resolution or range) of a translational slide and rotation of one of the dies (or wafers) relative to the other die or wafer.

Since the pad alignment testing structures and methods disclosed herein will allow for sufficiently accurate and efficient extraction of both translational and rotational pad alignment detection and measurement, this will be a highly useful method not only to keep track of misalignment but also to accurately categorize the probed die stack into a fail bin or pass bin. Thus, this method is very useful to predict not only the yield but also long term reliability during use since the method should result in fewer misaligned, less reliable devices being released to end users.

Also, since the method uses electrical circuits rather than imaging, this method will reduce the dependency on 3D X-ray and FA with IR imaging for example. For example, since this electrical probing can eliminate the need for IR imaging alignment, the need for a metal-free KOZ is eliminated and this solution can be used to reclaim not only die surface area for connections at the die surfaces, but also much or the entirety of the dielectric stack volume or column that would have been unused underneath a fiducial pattern. In this case, additional metal of metallization layers may be placed anywhere under a fiducial region including under spaces between the pad groups described above. Thus, by replacing the use of IR image fiducials and KOZs for post-bond alignment measurement with the use of electrically active pads as the fiducials, the IC dies now may have capacity for a significant number (potentially thousands) of additional connections per die. Thus, this solution provides developers a significant increase in flexibility for arranging the metallization on the IC dies, as well as tapping into transistor functionality in previously inaccessible regions of the die.

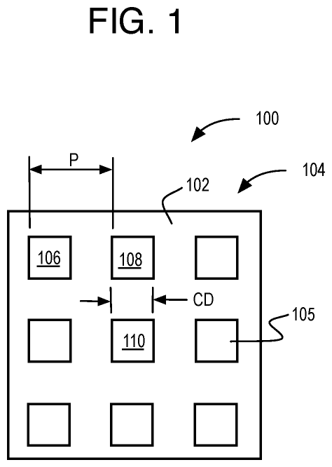

Referring to FIG. 1, as a preliminary matter, an example electronic device 100 is shown and may be a die 102 or a wafer with a die still on the wafer. An array 104 of conductive pads 105 are formed in rows and columns on the die 102 and have the same size and shape, here shown as squares with a width (or critical dimension (CD)) that may be 200-500 nm by one example. By one example form, electronic device 100 may be a die and may be bonded to another die where both dies have 500 nm×500 nm pads on a 4 mm×4 mm die for about 4 million interconnects. Other sizes and numbers of pads could be used as well.

A pad having the same size or dimensions herein refers to those pads within the same manufacturing tolerance dimensions, such as 525 nm or 475 nm exactly or about +/−5% tolerance by one example. A single row or column of pads 108 and 110 for example, all ideally fit within the critical dimension CD. A pitch P is the horizontal or vertical distance from adjacent pad to adjacent pad in a row or column where here from pad 106 to pad 108, and is measured here from same edge to same edge (as shown here from left edge to left edge) or center to center of the pads for example. This same arrangement of pads may be used for any of the electronic devices described herein.

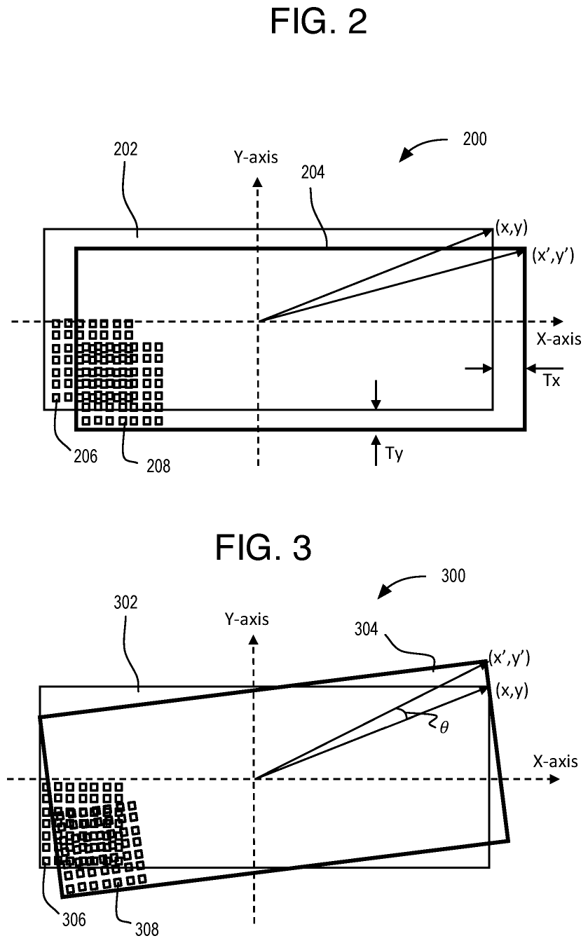

Referring to FIG. 2, an electronic device 200 has a pair of stacked dies including die 202, which may be a base wafer or die, and with pads 206, and die 204, which may be a monitoring or probing die, and with pads 208, where the die 204 has translated from die 202 such that the pads 206 are misaligned with pads 208 (the pads 206 and 208 are not to scale). The resulting misalignment translation (or translational error) from a point with coordinates (x,y) on die 202 to a corresponding point with coordinates (x′, y′) on die 204 is:

$$Tx = x ’ - x \qquad ( 1 )$$

$$Ty = y ’ - y \qquad ( 2 )$$

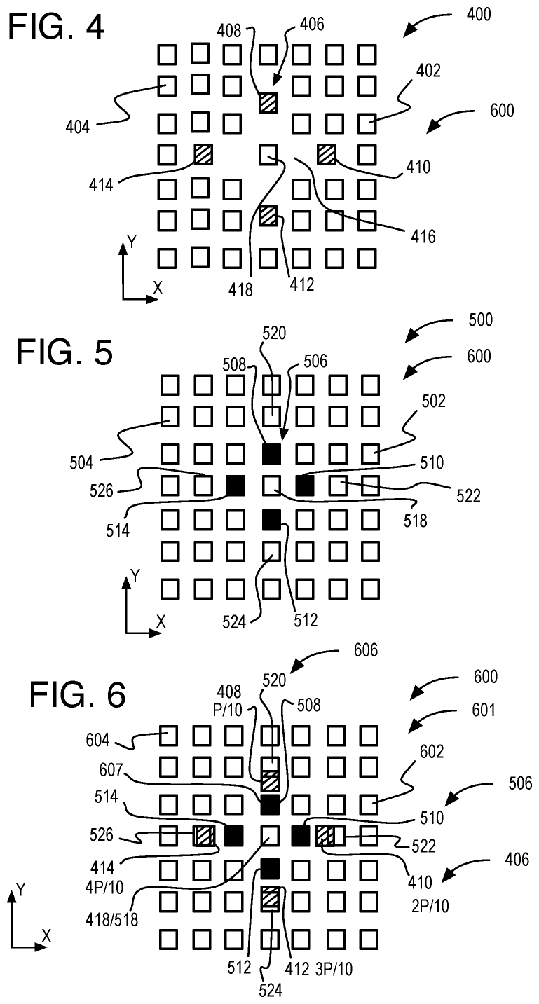

Referring to FIG. 3, an electronic device 300 has a pair of stacked dies including die 302, which may be a base wafer or die, and with pads 306, and die 304, which may be a monitoring or probing die, and where the die 304 has rotated from die 302 such that the pads 306 are rotationally misaligned from pads 308 (the pads 306 and 308 are not to scale). The resulting rotational misalignment (or rotational error) from a point (x,y) on die 302 to a corresponding point (x′, y′) on die 304, measured between rays when the rotation is at the center of the dies 302 and 304 is:

$$θ = rotational error \qquad ( 3 )$$

as shown on FIG. 3, and where a combined rigid body transformation equation may be applied as follows:

$$[ \begin{matrix}{x}^{′} \\ {y}^{′} \\ 1\end{matrix} ] = [ \begin{matrix}cos θ & - sin θ & Tx \\ sin θ & cos θ & Ty \\ 0 & 0 & 1\end{matrix} ] [ \begin{matrix}x \\ y \\ 1\end{matrix} ] \qquad ( 4 )$$

which is simplified to:

$$Δ x = - y θ + Tx \qquad ( 5 )$$

$$Δ y = x θ + Ty \qquad ( 6 )$$

where Δx and Δy are the observed (or measured) shifts, and (x, y) is the location of the pad alignment testing structure from the center of rotation. Testing circuits can use equations (1), (2), (5) and (6) to compute the translation and rotation measurements as described and applied in greater detail below. For the example here, the location of the testing structure is considered the center of a pad pattern formed by the testing structure, as described in the following, which may be a center of a cross or plus pattern of pads.

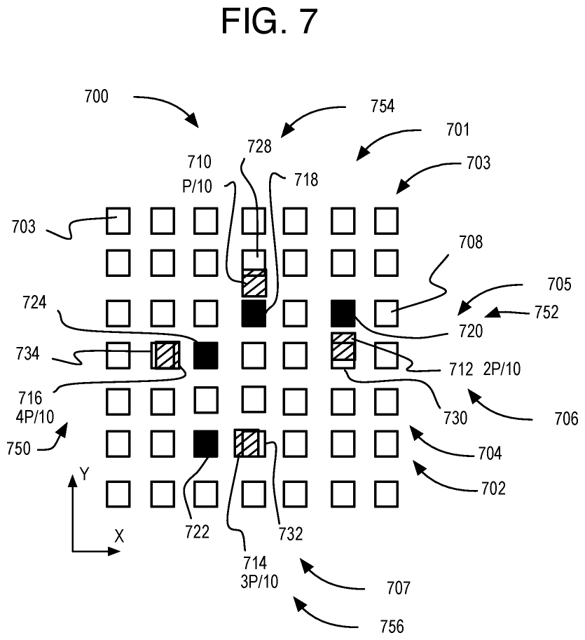

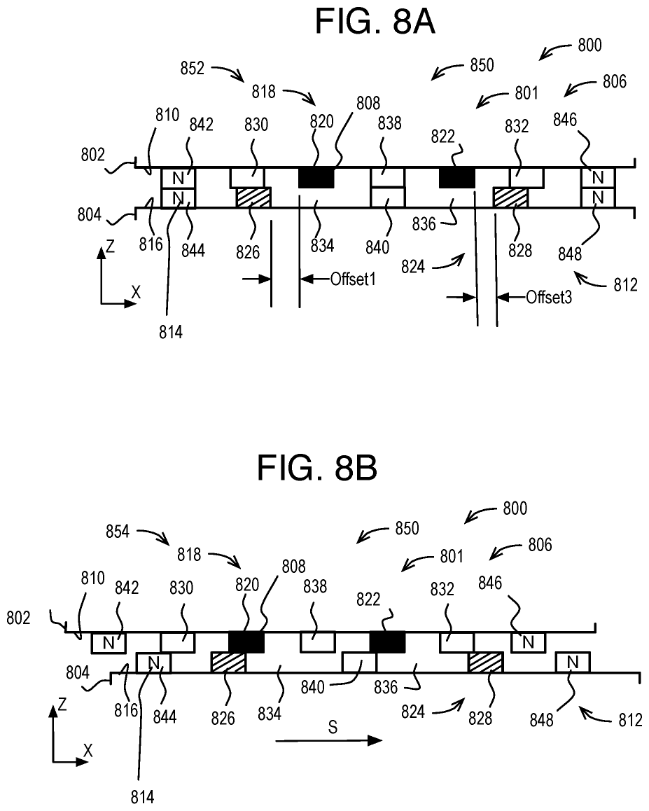

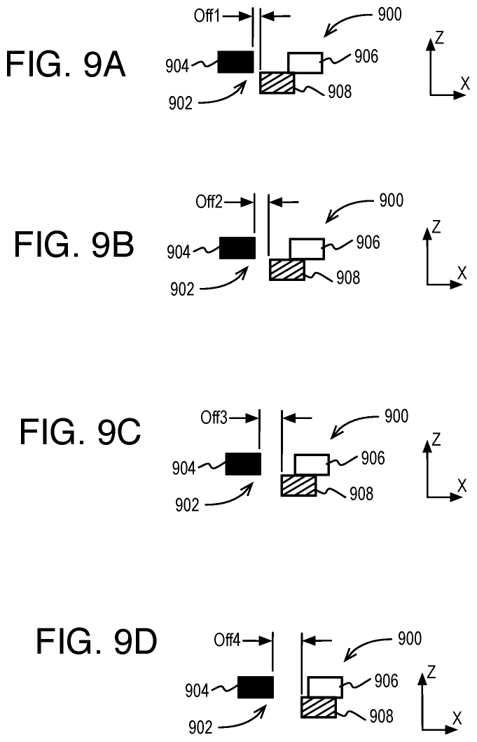

Referring to FIGS. 4-6, a pad alignment testing structure 600 (FIG. 6) includes pads from a bottom (or lower or base) electronic device 400 (FIG. 4) that may be a die or a wafer, or a die still on a wafer, and a top or upper (or probe or monitoring) electronic device 500 (FIG. 5) also may be a die or a wafer. The base device 400 may be over or under the probe device 500 to form a D2D, W2D, or W2 W arrangement for an integrated circuit (IC) device or package 601. For D2 W dies, one of the electronic devices 400 or 500 is an IC die not yet diced from a wafer (or to remain permanently on the wafer or part of the wafer to become a component of a package). Such a wafer may have many such electronic devices where a different IC die is being mounted to different electronic devices (or different dies) formed by or on the wafer. Otherwise, if both IC die 400 and 500 is not diced yet, W2 W bonding may be performed. Otherwise, the electronic device may be a package substrate or any specific component, device, or layer on such a package substrate, or a host component such as a system on a chip (SoC), printed circuit board (PCB), motherboard, and so forth. By one form, the IC die 400 or 500 may be a chiplet being bonded to a host IC die. The electronic device is not limited as long as an array of conductive pads for direct bonding, such as with HBIs, is provided. Many variations are contemplated.

The electronic device 400 may have a base pad array 402 of pads 404 spaced in rows or columns where a pitch P (as in FIG. 1) between pads in the rows and columns that may be less than 7-10 microns by one example, but as low as 2-3 or even 1-2 microns or less including sub-micron pitches. The examples used herein provide a pitch P=1.0 microns from pad to pad, while the widths (or CD) of the pads is 0.5 microns.

The device 400 has a base pad array 402 has a base pad pattern 406, here having four testing or ground (or grounded) base pads 408, 410, 412, and 414 (shown in blocks with diagonal hash lines). Each testing base pad 408, 410, 412, and 414 may be coupled to ground circuitry described below. Any of the non-pattern or surrounding pads of the base pad array 402 around the testing base pad pattern 406 may be coupled to other circuits used for many other functions or may be dummy (or floating) pads that are not electrically coupled to any circuitry and/or power source. The dummy pads are often used to maintain a certain pad density to avoid uneven structures during chemical metal polishing (or planarization (CMP)), as well as to avoid uneven distributions of other materials that will surround the pads (such as underfills) as well as to provide a desired uniform structural strength for the IC package 601.

In this case, however, empty spaces or pad locations (or spaces or positions) 416 are adjacent each base pad 408, 410, 412, and 414 of the base pad array 402 and between the base pads and, in this example, a dummy center pad 418 at a center of the base pad pattern 406. The omission of the pads at pad positions 416 are used to avoid physical interference that could be caused by pads at those locations that move relative to the probe pads as explained below. The testing base pads 408, 410, 412, and 414 may be arranged in a cross shape (or diamond or plus shape) shape as one example arrangement for pattern 406.

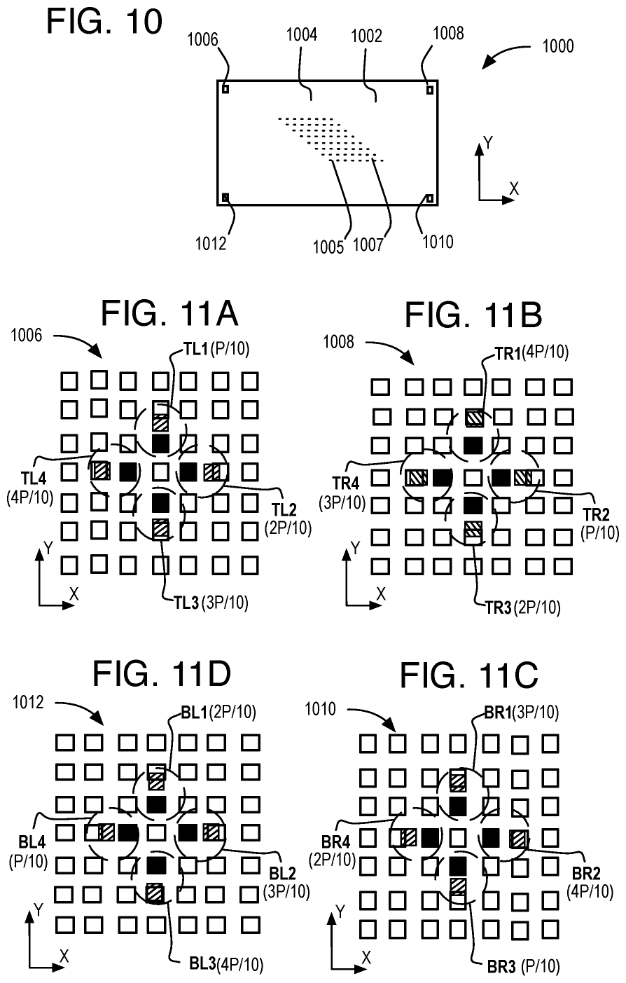

Referring to FIG. 5, the top (or upper or probe) electronic device 500 may have a top (or probe or monitoring) array 502 of pads 504 and that includes a probe (or probing) pad pattern 506 of probe pads 508, 510, 512, and 514 (shown as solid, filled-in blocks). For the probe pad pattern 506, the probe pads 508, 510, 512, and 514 are maintained at a spacing of pitch P that may be the same pitch as the non-pattern pads surrounding or near the pattern probe pads 508, 510, 512, and 514, and in the same pitch P as in base array 402. For the probe pads, the pattern 506 includes the probe pads 508, 510, 512, and 514 being a pitch P away from a center pad 518 at a center of the probe pad pattern 506 and that may be a dummy pad. The probe pads 508, 510, 512, and 514 may be in a cross shaped pattern 506 that aligns with the cross-shaped pattern 406, although other shapes may be used as discussed below with testing structure 700 (FIG. 7). A dummy pad 520, 522, 524, 526 may be respectfully placed behind (or farther away from the center of the pad 518) one of the probe pads 508, 510, 512, and 514.

In one form, the pads of the base pad array 402 are the same size and the pads of the top pad array 502 are the same size including pads in patterns 406 and 506, and by one form, the widths of the pads of both arrays 402 and 502 are the same, and this includes any of the pads in the patterns 406 and 506 and dummy pads near or within the patterns 406 and 506. By one form, the widths of the pads are 500 nm or 200 nm, or 200-500 nm. It should be noted that as the pad widths become larger, dishing problems may occur due to metallization polishing for example that may cause height gaps between vertically aligned pads that cannot touch in hybrid bonds, thereby resulting in unreliable products. Thus, by one form, the pads here are maintained as small as possible and at the same width (or size) and shape as described above.

Other than within the patterns 406 and 506, the pad arrays 402 and 502 may be completely or partially in a mirrored arrangement relative each other to bond the two arrays together. The pads 404 and 504 may be of uniform structure such as with an array of HBIs. The pads 404 and 504 may be part of any interconnect features that can be arranged in a uniform pitch array of metal pads where the pads are contacts, metallization features, or other interconnect features. By one form, all of the pads as well as any other metallization mentioned herein may have a conductive material, such as copper, but instead or additionally, may have other conductive materials.

Referring again to FIG. 6, pad alignment testing structure 600 has the base and probe patterns 406 and 506 placed over each other and in an ideal alignment with each other to cooperatively form a merged pad pattern 606 of the testing structure 600 with aligned non-pattern bonded pairs 604 and when the electronic devices 400 and 500 are stacked and ideally aligned with each other. In this case, the base array 402 is bonded to the top array 502, such as by hybrid bonding (with no solder bumps) by this example. Each of the four base pads 408, 410, 412, and 414 are respectively over or under one of the dummy pads 520, 522, 524, 526 and should not significantly interfere with the placement of the base pads 408, 410, 412, and 414 relative to the probe pads 508, 510, 512, and 514 since these dummy pads 520, 522, 524, 526 are farther away from the center of the merged pattern 606 than the base pads 408, 410, 412, and 414. The probe pads 508, 510, 512, and 514 are each placed over (or under) one the empty pad spaces 416 (FIG. 4).

As shown, each base pad 408, 410, 412, and 414 is respectively paired to an adjacent probe pad 508, 510, 512, and 514 so that each pair of pads (408, 508), (410, 510), (412, 512), and (414, 514) has a single base pad and a single probe pad. Each pair has different pads than any other pair so that no pair shares a pad with any other pair in the merged pattern 606. By one form, the term adjacent herein refers to a base pad being next to a probe pad whether or not the two pads are in physical or electrical contact, and even though the pads in each pair are from a different pad array (402 or 502). The pads in a single pair are sufficiently close (“adjacent”) to each other so that initially, and ideally, an offset exists between the pads in a single pair. Upon a mis-aligning shift of the patterns (406 or 506) relative to the other pattern (506 or 406), the pads in a single pair may be in physical contact with each other or at least can be placed close enough to each other to be electrically coupled or connected to each other. Thus, by one form, no intervening pad should be between the base pad and probe pad in a single pair that can block the physical contact and/or electrical coupling or connection between the two pads in a single pair.

In the present example, the merged pattern 606 is a cross pattern where a single pair is on each of the four arms 607 of the merged pattern 606. Each offset at a pair on the pattern may have a different offset length, and this is achieved by having the base pads 408, 410, 412, and 414 a different distance from the center of the pad 418, and in turn pattern 606, while the probe pads remain the same distance from the center of the pattern 606. It will be understood that the center of the patterns 406, 506, and 606 is at the same point within the arrays 402 and 502, and are properly aligned with each other, when the arrays 402 and 502 are ideally aligned with each other (disregarding unintentional misplacement of single pads). By one form, the center of the pattern 606 may be at the center of center pads 418 and 518 where the arms 607 of the cross pattern meet.

The different offset lengths may be a fraction of the pitch, herein being P/10, 2P/10, 3P/10, and 4P10 as indicated on merged pattern 606. While the detection of the electrical coupling at one of the pairs alone can indicate the direction of a misalignment once the pad arrays 502 and 602 are bonded, the variation in offset lengths is used to determine the distance or amount of the misalignment to determine a mis-alignment dimension also described in detail below. Thus, by one form, the offset values above in this example provide a misalignment measurement accuracy (or resolution) of 1/10 of the pitch.

By one approach, each probe pad 508, 510, 512, and 514 is coupled to a test channel thereby coupling each probe pad to a testing circuit to detect misalignments and compute misalignment direction and magnitude as described in detail below. It should be noted that while the examples herein describe the probe pads 508, 510, 512, and 514 being on the top electronic device 500, while the base or grounded pads 408, 410, 412, and 414 are on the base or bottom electronic device 400, the opposite could be used instead.

The pattern 606 is cross-shaped since the cross provides a compact shape that limits use of excessive footprint area of the devices 400 an 500 so that more pads can be used for other uses. Also, the use of the cross pattern merely needs four test channels to detect electrical coupling at each pair in the cross pattern. Thus, only 16 channels are needed when four testing structures are used on a single IC package 601 as described below, thereby minimizing the amount of metallization on the IC device 601 for the testing structure 600.

Referring to FIG. 7 for another example form, instead of providing the merged pattern 606 with a cross-shape, other patterns can be used instead as long as two of the pairs have offsets (or offset lengths) that are parallel to the columns (or here Y-axis direction) of the base and top arrays 402 and 502, and two other pairs are parallel to the rows (or here X− direction) of the arrays 402 and 502. The row pairs should each indicate misalignment in a different opposite direction (X+ and X−) parallel to the rows, while the two column pairs should indicate misalignment in two opposite directions (Y+ and Y−) parallel to the columns. The pairs should be near each other to provide a compact pattern as described with the cross pattern, although the pairs could be spread out from each other when desired. Thus, to demonstrate this feature, an alternative IC package 700 has stacked base electronic device 701 under a top electronic device 702 respectively with a base pad array 703 under, and bonded to, a top probe pad array 704. The base array 703 has a base pad pattern 705, and the top array has a probe pad pattern 706 similar to patterns 406 and 506 to form a merged pattern 707, and next to non-pattern bonded pad pairs 708.

The merged pattern 707 may have many different arrangements. The example here has two row pairs 750 and 752 near each other, each respectively with a probe pad 722, 724 and a base pad 714, 716 under a dummy pad 732, 734. The merged pattern 707 also has two column pairs 754 and 756, each respectively with a probe pad 718, 720 and a base pad 710, 712 under a dummy pad 728, 730. When the probe pads 718, 720, 722, 724 are coupled to a power source and testing circuit (not shown) and the base pads 710, 712, 714, 716 are coupled to ground circuitry, the testing circuit can detect direction and magnitude of misalignment in all four directions (X+, X−, Y+, Y−) similarly to the detection of misalignment for the merged cross-pattern explained below.

As to other variations in the pad patterns, it will be appreciated that more than four pads could be used for greater accuracy such as 8 pads to form a square pattern with four more pad-pairs with base and probe pads at the square corners of the cross pattern and surrounding a center pad, or other patterns with various numbers of pad-pairs.

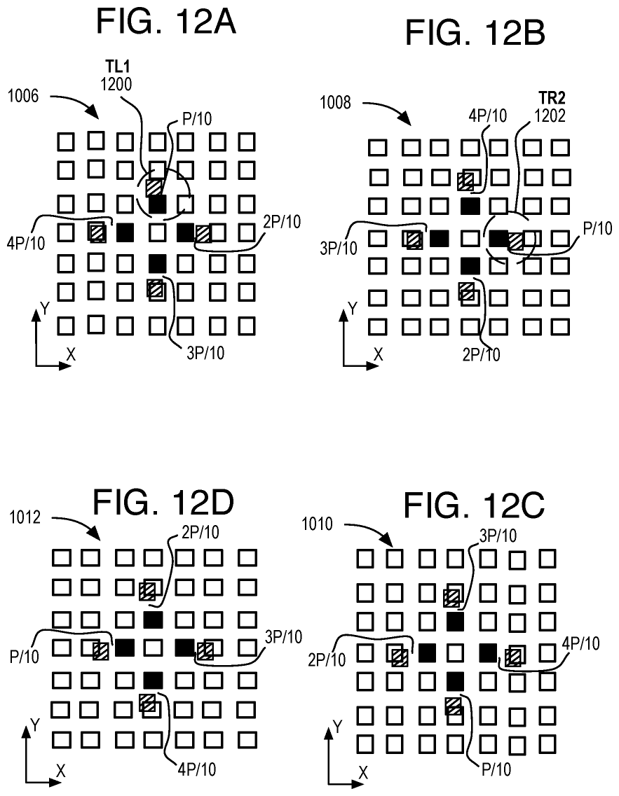

Referring to FIGS. 8A and 8B to further demonstrate the pad offsets and pad alignments (and misalignments), and returning to the merged cross pattern, an integrated circuit (IC) device 800 has an electronic device 802 that is a probe die or wafer over an electronic device 804 that is a base die or wafer, where the two devices 802 and 804 are in ideal alignment. Dies 802 and 804 respectively have a probe array 806 of pads 808 extending from a layer 810 of the probe die 802, and a base array 812 of pads 814 extending from a layer 816 of the die 804. By one form, the layers may be metallization layers or dielectric layers.

The IC device 800 also has a testing structure 801 that includes a probe pad pattern 818 with probe pads 820 and 822 similar to that described above with testing structure 600, and a base pad pattern 824 with base pads 826 and 828, also as described above with testing structure 600. The base pads 826 and 828 are respectively under dummy pads 830 and 832 of pad array 806. The probe pads 820 and 822 are respectively over empty pad spaces 834 and 836 within the base array 812. A dummy center pattern pad 838 of the probe pattern 818 is over a dummy center pattern pad 840 of the base pattern 824.

The IC device 800 has arrays 806 and 812 in ideal alignment 850 as shown by the non-pattern pads N being sufficiently aligned, where N pad 842 is aligned with N pad 844, and N pad 846 is aligned with N pad 848. In this ideal alignment between arrays (or dies or electronic devices 802 and 804), each paired adjacent probe and base pads in a merged pad pattern 852 of the testing structure 801 are offset from each other. This is demonstrated by offset1 between probe pad 820 and base pad 826, and offset2 between probe pad 822 and base pad 828. These two pairs of pads may be on opposite legs of a cross-pattern as explained with merged pattern 606 (FIG. 6), but may be in other pattern shapes or arrangements as explained with merged pattern 707 (FIG. 7). Offset1 and offset2 are different distances and may have those distance values as described above with merged pattern 606.

Referring to FIG. 8B, here IC device 800 has die 804 shifted laterally to the right as shown by arrow S and relative to die 802 into a misaligned state 854. In this case, the dies 802 and 804, and/or arrays 806 and 812 are misaligned with each other as shown by N pads 842 and 846 now being spaced from N pads 844 and 848 respectively, rather than being in contact. Note that a mis-aligned state of the electronic devices refers to either the electronic devices themselves being misaligned during bonding where the position of the pad arrays of each device is in a proper position on each device but the alignment process during bonding did not have correct alignment, or printing where the electronic devices themselves are aligned correctly during an alignment process before or during bonding but individual pads, or parts of the arrays, are in a wrong position within the arrays and on the devices.

In the case of the misalignment state 854, probe pad 820 is now in contact with base pad 826. When probe pad 820 receives current from a testing circuit coupled to the probe pad 820, a leakage or short detection circuit can detect a non-zero current since the base pad 826 is coupled to ground. This will indicate (1) that the pads are misaligned, (2) the direction of the misalignment depending on which pad-pair is in contact (or which multiple pad-pairs are in contact either on a single pattern or when multiple testing structures are being used on the device 800), and (3) the magnitude of the misalignments depending on the distance of the offset(s) that were collapsed.

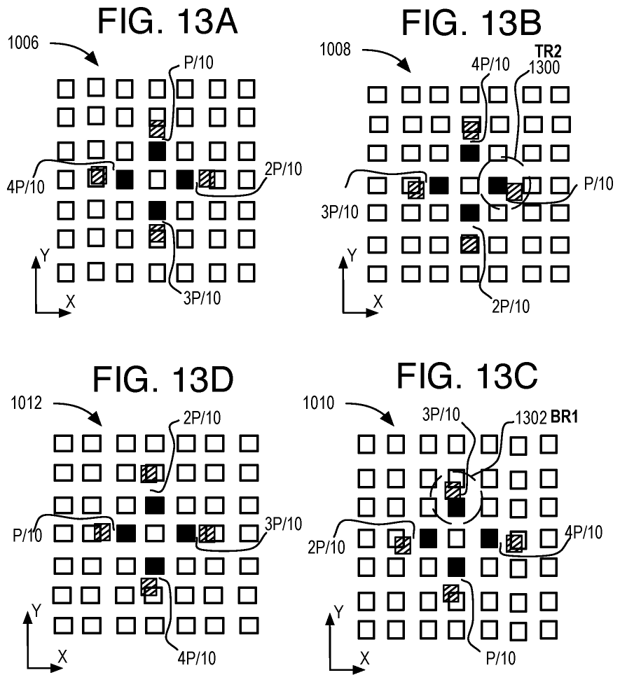

Referring to FIGS. 9A-9D, more views of an offset setup 900 of pads is provided and that may be used on any of devices mentioned above. Here, offsets 902 between a probe pad 904 and a base pad 908 are shown and labeled off1 to off4 for the four offsets that may be used for the cross pattern described above. The base pad 908 is under a dummy pad 906. The size of the offset 902 as well as the number of pads may depend on the resolution that is desired. As mentioned above, for a 1/10 pitch resolution, the offsets off1 to off4 are respectively 1/10, 2/10, 3/10 and 4/10 the pitch P. Since a typical hybrid bond pad size (CD) is half of the pitch, an alignment error of the size of a half the pitch will result in massive failure and will be detected by many other electrical structures. The scope of this testing structure is able to detect less than the half the pitch alignment errors.

By one form, if a resolution desired is R and P is the pitch:

$$( P / 2 R ) - 1 = L \qquad ( 7 )$$

where L is the number of probe-base pad-pairs with an offset that are needed to measure the misalignment at a desired resolution. For example if R=P/10 (100 nanometer resolution for 1 micron pitch), (P/2R)−1=4. Here, four (4) pad-pairs placed in P/10, 2P/10, 3P/10, 4P/10 offset distances should be able to provide 1/10^{th} of pitch resolution. A pad-pair placed at 5P/10 will short if pad size is P/2 so that it is not necessary as mentioned above.

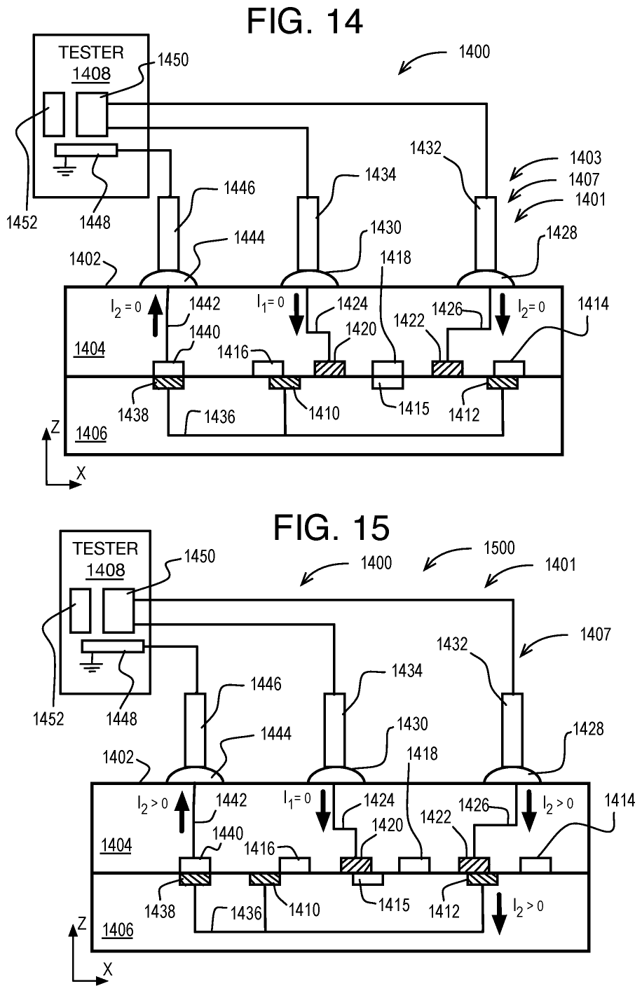

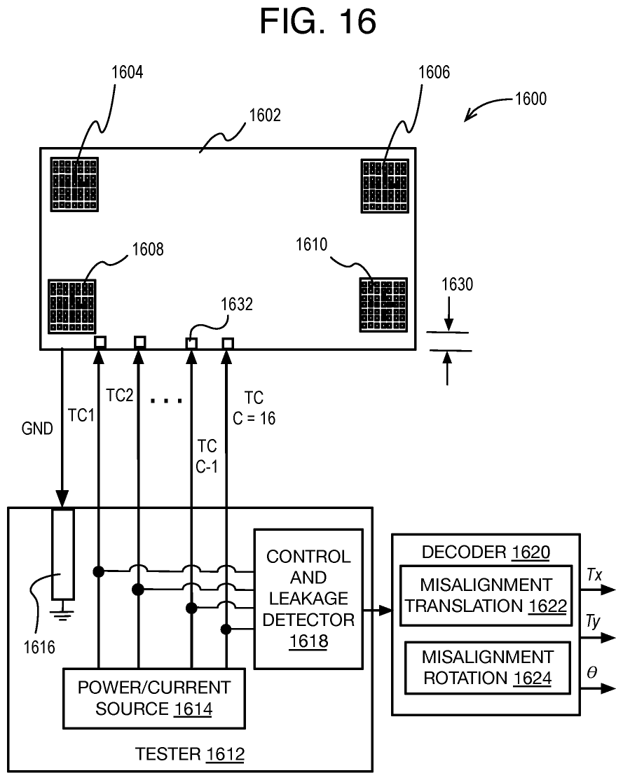

Referring to FIG. 10, the measurement of both translational and rotational misalignment can be achieved at a certain resolution by placing testing structures 1006, 1008, 1010, and 1012 at multiple places on an IC device 1000 with a stack of dies 1002 and 1004. The dies 1002 and 1004 may respectively have pad arrays 1005 and 1007 bonded to each other as described with IC devices or testing structures 200, 300, and 600 for example. In this example, it was found that the testing device 1006, 1008, 1010, and 1012 may be positioned at four different corners of a rectangular die stack of device 1000 in order to better detect and compute rotational misalignment. The IC device 1000 is used to show various examples of an ideal alignment and misalignment of the multiple testing structures including a top left (TL) testing structure 1006, a top right (TR) testing structure 1008, a bottom right (BR) testing structure 1010, and a bottom left (BL) testing structure 1012 in FIGS. 11A to 13D as follows.

Referring to FIGS. 11A-11D, an ideal alignment between dies 1002 and 1004 is shown where none of the pad-pairs with an offset are in contact. In other words, each pad-pair is separated by the offsets and none have a collapsed offset causing pads in a pair to be in contact. The pads are shown in the cross pattern where the pad-pairs are numbered by position within the cross pattern, such that, as viewed in plan view shown, an upper pad-pair is in position 1, and the remaining positions 2 to 4 are then counted clockwise. Each position then may be designated by which testing structure (or position of the testing structure) it is on, and then which position number within the cross pattern. Thus, for example, pad-pair TR1 is on the top right testing structure at position 1 (upper) on the cross pattern.

Each pad-pair position is also labeled with the offset distance or length, from P/10 to 4P/10 labeled in a clockwise order as well. It should be noted that each testing structure 1006, 1008, 1010, and 1012 has the offsets of the same length at a different position within its cross pattern. Thus, for example offset P/10 is at upper TL1 position on testing structure 1006, while offset P/10 is at the right position TR2 on testing structure 1008. By the example here, a position of the same offset length is rotated clockwise 90 degrees to the next testing structure in clockwise order on the IC device 1000. Other orders or arrangements of the offset lengths may be used instead as long as each pad-pair position (here 1 to 4) alternatively has all of the available offset lengths across all of the testing structures being used in order to be able to measure misalignment at the full range possible at the misalignment measurement resolution being used. Thus, by using testing structures in four corners with 0 degree, 90 degree, 180 degree and 270 degree rotations of the offset lengths as shown, this results in all four directions (+/−x and +/−y) having four different pad offsets at each of the testing structures.

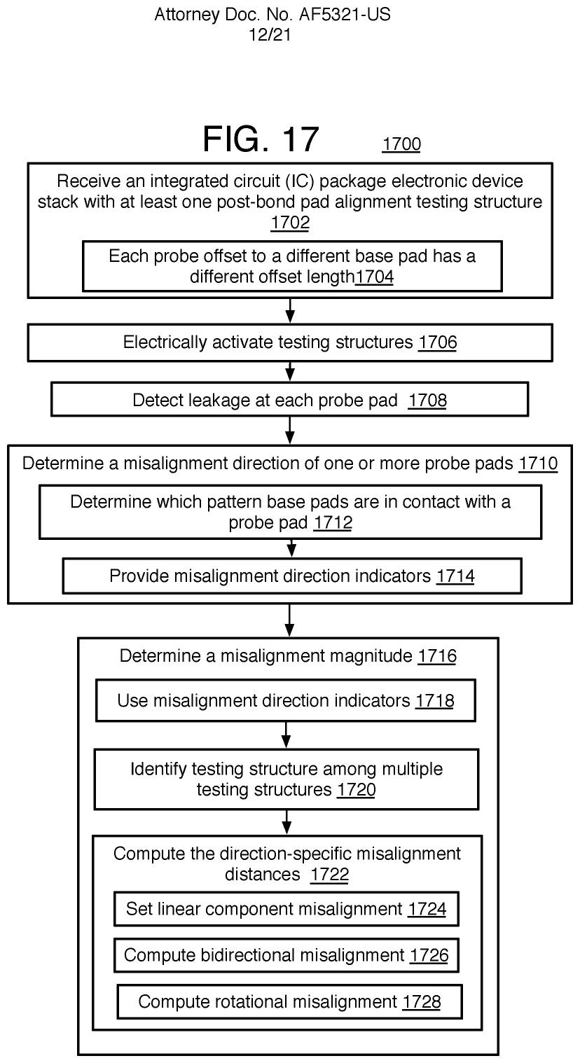

Referring to FIGS. 12A-12D, the pad alignment for device 1000 is shown when a translational misalignment occurs and is detected due to contact at pad-pairs TL1 1200 on testing structure 1006 and TR2 1202 on testing structure 1008, and only at these two pad-pairs. The testing circuit or testing unit will detect current leakage at these two pad-pairs indicating the contact. Since the two pad-pairs are an upper pair and a right pair that are exterior sides of the cross pattern, the direction of the misalignment is to the upper right relative to IC device 1000 on FIG. 10. Since both of these pad-pairs have an offset of P/10, the misalignment is between 2P/10 and P/10. Since the misalignment is at two different pad-pair directions (X and Y), it is a bidirectional translation misalignment that can be measured as 1/10 of P in Tx and Ty.

More specifically for two testing structures with leakage, when two or more pad-pairs from different testing structures at four corners of a device 1000 have contact and are on the same side (position number) of the pad patterns, this indicates translation misalignment in a single direction. When the two pad-pairs with contact are on opposite sides (position numbers) of the pad patterns, this indicates rotational misalignment. When the two pad-pairs with contact are at pattern positions that are separated by 90 degrees, and both pad-pairs are on different exterior sides of the pad patterns (closest to an outer edge of the device 1000), then this indicates bidirectional translation. When the pad-pairs with contact are 90 degrees apart on their patterns, but one of the pad-pairs is an interior pad-pair (closer to, facing, or on a line toward another of the testing structures), then this can indicate both rotational and translational misalignment.

Also then, when only one testing structure leaks, only translational information is available. Otherwise, when three or more structures leak, more information is available and the rotational angle can be calculated and retested. At least two testing structures are needed for rotational angle calculation, while a third or fourth equation reduces error.

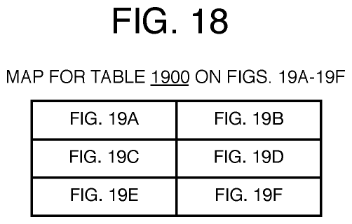

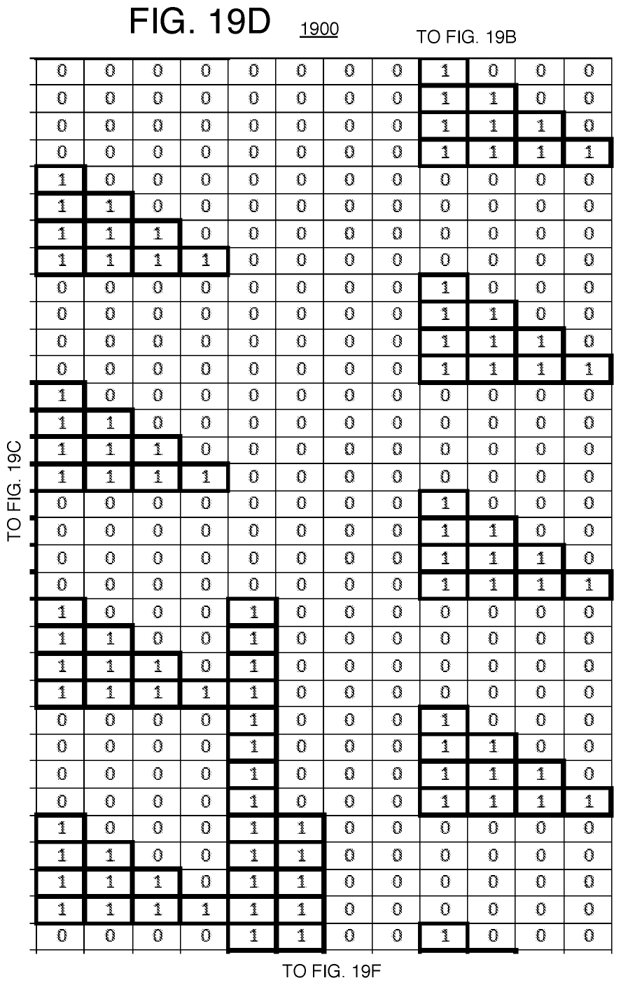

Referring to FIGS. 13A-13D, the pad alignment for device 1000 is shown when a translational and rotational misalignment occurs and is detected due to contact at pad-pairs TR2 1300 on testing structure 1008 and BR1 1302 on testing structure 1010, and only at these two pad-pairs. The testing circuit or testing unit will detect current leakage at these two pad-pairs indicating the contact. Since the two pad-pairs are a right pair on structure 1008 and an upper pair structure 1010, the direction of the misalignment is rotational to the lower right in a clockwise direction relative to one die 1002 to the other die 1004 on FIG. 10. Since BR1 has a larger interior offset (3P/10) than at the exterior TR2 (P/10) offset, this indicates a translation shift to the right greater than P/10 and a rotation misalignment of 0.05 degrees clockwise. The computation of the rotational misalignment is explained below with process 1700 (FIG. 17).

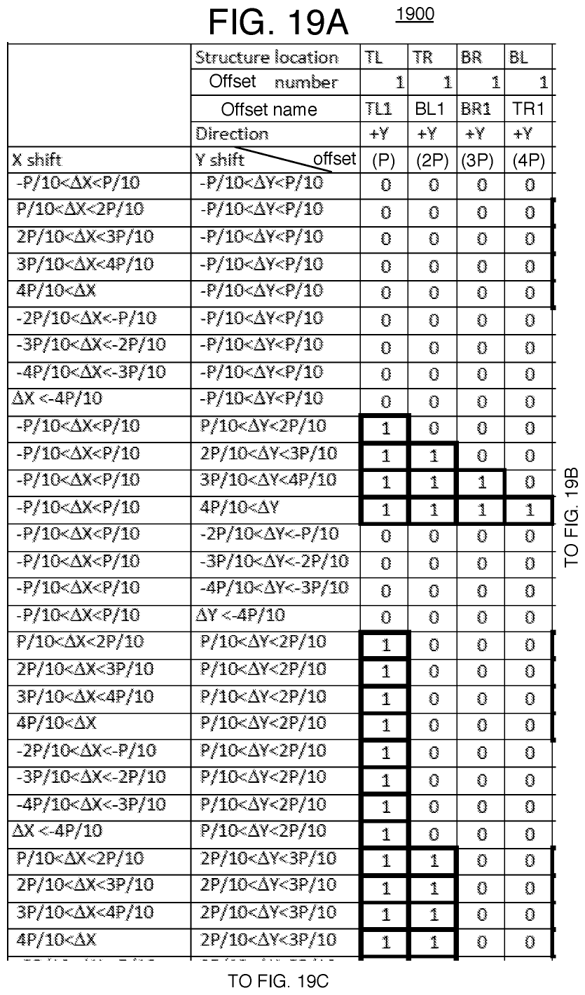

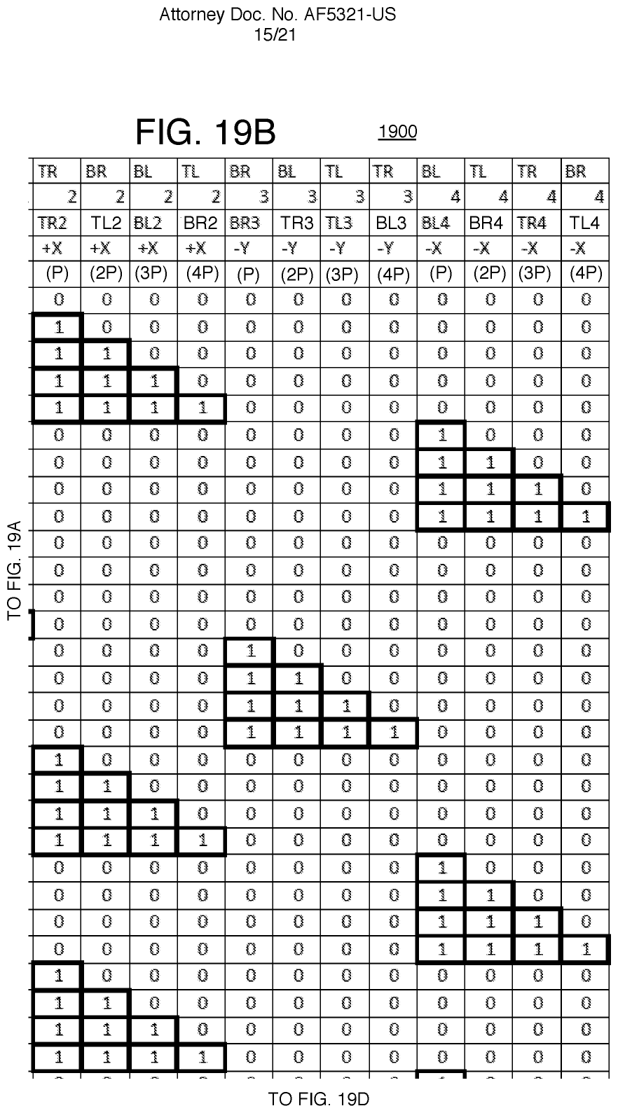

Referring to FIGS. 14-15, an IC pad alignment monitoring system 1400 may have an IC device 1401 with a stack 1402 of electronic devices 1404 and 1406 with a testing structure 1407, and a tester unit or circuit 1408 (or simply tester or ATE, although a customized or unique testbench could be used) electrically coupled to the electronic device 1404. The structure, materials, and features of the IC device 1401 and stacked devices 1404 and 1406 are as discussed with the other devices above such as at least with IC device 800 and devices (or dies or wafers) 802 and 804 (FIGS. 8A-8B) above. A setup 1403 shows the devices 1404 and 1406 in ideal alignment, while setup 1500 shows devices 1404 and 1406 in a misalignment.

The electronic device 1406, which may be a base die for example, has base pads 1410 and 1412, and a dummy pad 1415 forming a base pad pattern are arranged for pad alignment testing and may be in a cross pattern or other pattern as describe above. The base pads 1410 and 1412 may be coupled to ground circuitry 1436 to ground the base pads. The ground circuitry 1436, which may have a ground plane, may include a ground pad 1438. The ground pads 1438 and 1440 should remain in contact despite a measurable misalignment of the base and probe pads because the pads are centered with each other and should only misalign by slightly less than half the pitch when the misalignment is measurable.

The electronic top or probe device 1404 may have a pattern of probe pads 1420 and 1422, as well as dummy pads 1414, 1416, and 1418 that are to be respectively placed adjacent pads 1412, 1410, and 1415 of the device 1406. The device 1404 also has a grounding pad 1440 to couple to ground pad 1438. The device 1404 also has circuitry 1424 to electrically couple the probe pad 1420 to a source or external probe pad or other conductive feature 1430, and circuitry 1426 to couple probe pad 1422 to source or external probe pad or other conductive feature 1428. Circuitry 1442 couples grounding pad 1440 to an external ground pad 1444. By one form, the external pads 1428, 1430, and 1444 are at least accessible to be electrically coupled to removable test probes (or leads) or other testing circuitry 1432, 1434, and 1446 respectively, and such as a sort or test probe needle. The external probe pads (or just external pads) 1428, 1430, and 1444 may be formed with solder bumps or copper bumps/pads and tested using MEMS or cantilevered probes. By alternative forms, the probes 1432, 1434, and 1446 may be permanent on the device 1401. It also will be appreciated that the external pads 1428, 1430, and 1444 may be external during testing, but then may be subsequently embedded within device 1401 or removed for example.

The external probes 1432, 1434, and 1446, may be electrically coupled to the tester unit 1408. The tester unit 1408 may have, or be electrically coupled to, ground circuitry 1448 which is coupled to the ground probe 1446. A control and leakage detection unit 1450 may be electrically coupled to external probes 1432 and 1434, and a power source or power source circuitry 1452 may provide current to the external probes 1432 and 1434 and that is monitored by the control and leakage detection unit 1450. The control and detection unit 1450 controls the activation of current flow to the external probe pads 1432 and 1434, and in turn the pattern probe pads 1420 and 1422, and then detects current flowing at the external probes 1432 and 1434 when any of the pattern probe pads 1420 and 1422 are in contact with any of the base pads 1410 and 1412.

In the ideally aligned setup 1403, none of the pattern probe pads 1420 and 1422 are in contact with base pads 1410 and 1412 so the current is zero (I₁=0 and I₂=0 as shown). Thus, the detection unit 1450 will not detect any current flowing to the external probes.

Referring to FIG. 15 for a misalignment arrangement or setup 1500, the dies 1404 and 1406 may be misaligned and base pad 1412 is in contact with pattern probe pad 1422. In this case, this electrically couples the external probe 1432, through pattern pads 1422 and 1412 and ground pads 1438 and 1440, to ground circuitry 1448. This results in the detection unit 1450 detecting a flow of current from the tester 1408 (I₂>0). Due to the position of the pattern pads in contact and offset at the pads in contact, the direction and magnitude of the misalignment can be computed as explained herein.

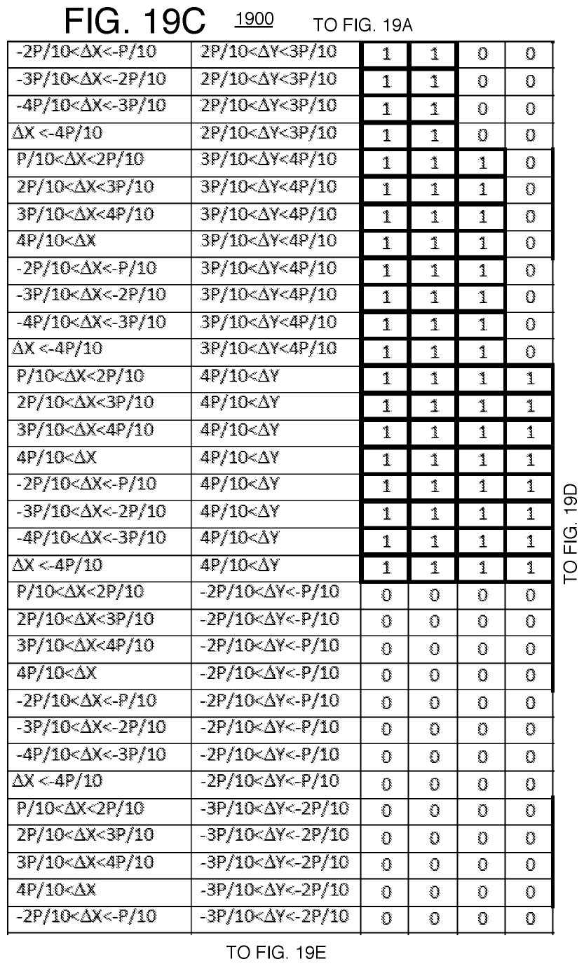

Referring to FIG. 16, a pad alignment testing system 1600 has an IC device 1602 of at least two electronic devices with pad arrays bonded to each other as described herein. The IC device 1602 has four testing structures 1604, 1606, 1608, and 1610, similar to that of device 1000 (FIG. 10). The IC device 1602 also may have external probe pads 1632 to electrically couple pad-pairs of the testing structures 1604, 1606, 1608, and 1610 to the tester unit 1612. Each pad-pair in the testing structures may have it own channel to the tester through its own external probe pad 1632. The external probe pads 1632 may be placed on IC device 1602 wherever it is most efficient, and in the example here the pads 1632 are shown in a margin or frame 1630 for the IC device to avoid using any area or volume that can be used for pad arrays or other devices on the IC device. The pads 1632 could be placed physically at, or nearer to, each testing structure 1604, 1606, 1608, and 1610 instead. Many variations are contemplated. Each pad-pair may have one of the channels TC1 to TCC where the channel number c=1 to C, and by one example C=16 channels for four pair-pads at each of four testing structures.

The tester unit 1612 may have a power/current source unit or circuitry 1614 that provides current to the channels TC1 to TCC. The current may be up to 0.1 mA and the power source circuitry may have up to 5V. Since the leakage measurement is more sensitive at lower current limits while lower current has more noise, higher current may be used as long as the circuit has capacity for the current. With current dimensions (about 100 nm of Cu metal lines), about 0.1 mA may be the current limit.

The tester unit 1612 also may have ground circuitry 1616 that couples the base pads on the testing structures 1604, 1606, 1608, and 1610 through circuitry GND to ground. Such ground circuitry may be common on the base die/wafer or may include at least one ground plane on an entire die.

A control and leakage detector unit 1618 may have circuitry to turn the current from the power circuitry 1614 on and off as desired and to the channels TC1 to TCC. This may involve using individual tester channel or time division multiplexing circuit using single channel.

In this case, external lab or testbench equipment as tester 1612 may be used to probe the pads using custom probes or probing cards around the IC die that are electrically coupled to power and I/O pads on a wafer for example, and in this case, this routing may be through frame pads.

As for the detection of the current when leakage or a short occurs, the control and detection unit 1618 detects the leakage by measuring the current through the tester's built in current meter. The tester will function in Voltage source and current measure (VSIM) mode. A specific voltage (Typically 5 V) is sourced and a specific current level (typically 0.1 mA) may be detected based upon the shorting or lack of shorting. By one alternative, the detection could be performed by detecting a resistance or capacitance on each of the channels.

Once the control and leakage detection unit 1618 detects current at one or more of the channels TC1-TCC, the identification of those channels may be provided to a decoder. This may be performed by filling a register or database table with indicators of pad-pairs assigned to each row in the table and the control and leakage detector unit 1618 simply turns the row in the table and of a pad-pair on or off with a binary flag or code, for example. Other variations include an output of a time division multiplexer wherein the individual channel will flag based upon the output from a specific time domain assigned to the specific channel.

The decoder 1620 has a misalignment translation unit 1622 to compute translations Δx and Δy for all of the testing structures 1604, 1606, 1608, and 1610, and outputs translation direction and magnitude values Tx, Ty. A misalignment rotation unit 1624 computes rotation misalignment θ as described below.

Referring to FIG. 17, an example process 1700 of post-bond pad alignment testing is performed according to at least one of the implementations disclosed herein and describes an example post-bond pad alignment using the arrangement of the pad patterns described above with FIGS. 3-13D. Process 1700 includes operations 1702 to 1728 numbered evenly, and electronic systems, IC devices, testing structures, and/or pad arrangements of FIGS. 3-13D may be referred to herein where appropriate.

Process 1700 may include “receive an integrated circuit (IC) package electronic device stack with at least one post-bond pad alignment testing structure” 1702, where in the present example, four testing structures are used, one at each corner of an IC device, although other arrangements could be used instead. The IC device is as described above with at least two electronic devices being at least two die, two wafers, or one of each, where one of the two electronic devices for example has a pad array bonded to the pad array of the other electronic device. For this example, it will be assumed the two electronic devices are dies.

One of the dies has a base pad array with a base pad pattern of base pads electrically coupled to ground circuitry, and the other die has a probe pad array with a probe pad pattern with probe pads electrically coupled to a testing unit that provides current to the probe pads during pad alignment tests. The base pads and probe pads cooperatively form a merged pattern of one of the testing structure.

Operation 1702 may include “each probe pad offset from a base pad has a different offset length” 1704. Thus, as described above for a cross-pattern as the merged pattern, and by one example form, each pad-pair in the pattern has a different offset between a probe pad adjacent a base pad. Also as mentioned, and by one example form, each offset length has a different position at each of the testing structures as explained with FIGS. 11A-11D. By one form, the resolution of the offsets is set at 1/10 the pitch here being 1/10 a micron, where the four offsets are P/10, 2P/10, 3P/10, and 4P/10, although other offset lengths could be used instead.

Process 1700 may include “electrically activate testing structure” 1706, and where a tester unit may turn on the power or current to the multiple channels coupled to the probe pads as described above with system 1600 (FIG. 16). As mentioned, each pad-pair with an offset may have its own channel, so that in the present case only 16 channels are needed for all four testing structures. The Voltage may be turned on for a specified period such as 10 milli seconds so that the voltage is sufficient to have stable leakage detection and avoid detecting an initial spike in current due to routing circuit capacitance, and this may be performed two times by one example.

Process 1700 may include “detect leakage at each probe pad” 1708, and where the tester unit may have a leakage detection unit (whether as part of a control that controls the current or as a separate unit or module) as with detector 1618 described above, and coupled to all of the channels to the probe pads.

Process 1700 may include “determine a misalignment direction of one or more probe pads” 1710, and this operation 1710 may include “determine which pattern base pads are in contact with a probe pad” 1712. The leakage detection unit may monitor each of the channels separately so that when a probe pad is in contact with a base pad at any pad-pair, the identification of that pad-pair is determined by which channel has a flow of electricity.

As mentioned, the direction of the misalignment can be determined by which pad-pairs are in contact. Thus, operation 1710 then may include “provide misalignment direction indicators” 1714 such that the direction of the misalignment, when translation is in a single direction, bidirectional translation, and/or rotation, is inherently included in the identification of the pad-pairs with contact (as explained with FIGS. 12A-12D above), via the channels to each pad-pair, and in turn codes provided to a decoder. Thus, the identification of the pad-pairs by flags or codes in a table as mentioned above with unit 1618 for example or a truth table based on translation and rotation are then provided to a decoder or other unit to perform the misalignment computations. A truth table can be calculated based upon the transformation equations (1) and (2) herein, and the table may be coded in the tester to provide output.

To continue the example from FIGS. 10-11D with the 16 probe pad channels, the following table shows the pad-pair locations to be used for the misalignment computations.

TABLE 1
Pad-Pair Offset Length location on Testing Structures

| | Testing | Pad-Pair | | X/Y Resolution |
|---|---|---|---|---|
| Channel | Structure | number | | P = pad to |
| Number | Location | (position) | Name | pad distance |
| 1 | Top Left | 1 | TL1 | P/10 |
| 2 | Top Left | 2 | TL2 | 2P/10 |
| 3 | Top Left | 3 | TL3 | 3P/10 |
| 4 | Top Left | 4 | TL4 | 4P/10 |
| 5 | Top Right | 1 | TR1 | 4P/10 |
| 6 | Top Right | 2 | TR2 | P/10 |
| 7 | Top Right | 3 | TR3 | 2P/10 |
| 8 | Top Right | 4 | TR4 | 3P/10 |
| 9 | Bottom Right | 1 | BR1 | 3P/10 |
| 10 | Bottom Right | 2 | BR2 | 4P/10 |
| 11 | Bottom Right | 3 | BR3 | P/10 |
| 12 | Bottom Right | 4 | BR4 | 2P/10 |
| 13 | Bottom Left | 1 | BL1 | 2P/10 |
| 14 | Bottom Left | 2 | BL2 | 3P/10 |
| 15 | Bottom Left | 3 | BL3 | 4P/10 |
| 16 | Bottom Left | 4 | BL4 | P/10 |

Process 1700 may include “determine a misalignment magnitude” 1716, and operation 1716 may include “use misalignment direction indicators” 1718, and “identify testing structure among multiple testing structures” 1720. As shown on the Table 1 above, the amount of offset, and in turn minimum amount of linear misalignment Tx and Ty can be determined depending on which pad-pair (or channel) has leakage or a short. The Table 1 also shows which testing structure had the leakage, and in turn which testing structure had the leakage and the position of the pad-pair with the leakage within the testing structure.

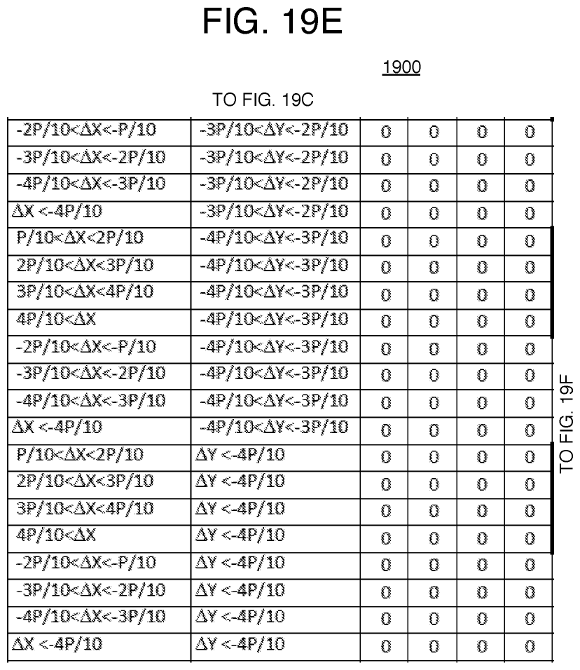

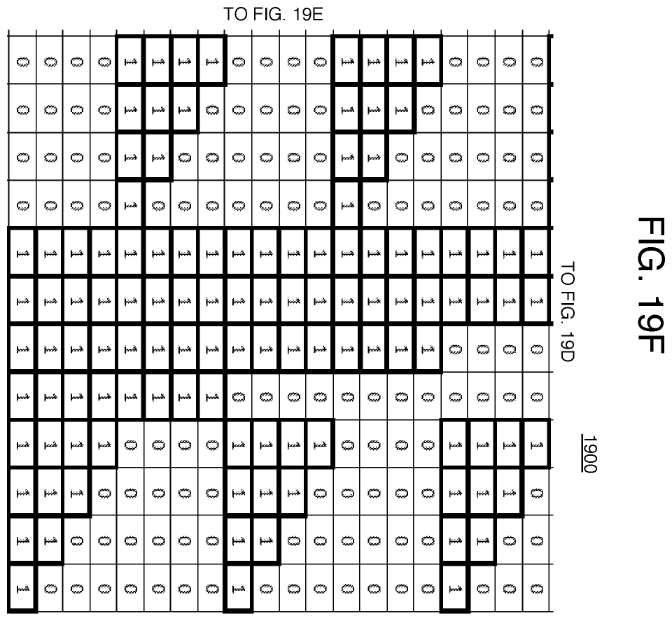

Referring to FIGS. 18 and 19A-19F, a table 1900 (mapped on FIG. 18) provides the identification of each pad-pair that has leakage (1) and no leakage (0) and the translational alignment x and y shifts (or in other words Tx and Ty from equations (1) and (2) recopied down below) that was determined by identification of the pad-pairs with the leakage. The table 1900 can be used to determine pure translation only misalignments, and can provide resolution of 1/10^{th} of the pitch. When a particular line in the truth table 1900 is satisfied, the corresponding shift in X and Y direction can be identified and information can be decoded.

$$Tx = x ’ - x \qquad ( 1 )$$

$$Ty = y ’ - y \qquad ( 2 )$$

where x and y are the expected locations of the top die (with probe pads) with respect to base die/wafers, where x′ and y′ are actual locations of the top die with respect to the base die/wafers, and Tx and Ty also equals the offset of a pair-pad with leakage in each direction (X and Y), and for each testing structure.

Operation 1716 may include “compute the direction-specific misalignment distances” 1722, and this operation may include “set linear component misalignment” 1724. This is Tx and Ty from each testing structure. The distances in each direction (X and Y) may be averaged or otherwise combined for all of the testing structures.

Operation 1722 may include “set bilinear misalignment” 1726. When desired, a bilinear misalignment may be computed by using Tx and Ty in a Pythagorean theorem equation.

Operation 1722 may include “set rotational misalignment” 1728. To determine the rotational error θ, at least two testing structures are needed since there are three unknown variables (Tx, Ty, θ). Hence, this computation should have at least two testing structure (two testing structure locations will have four equations) to extract the translation and rotation errors.

Also as copied from above, the rotational alignment error is obtained from equations (5) and (6):

$$Δ x = - y θ + Tx \qquad ( 5 )$$

$$Δ y = x θ + Ty \qquad ( 6 )$$

where θ is computed by using multiple equations from the multiple testing structures as follows. As one example computation, say a 10 mm×10 mm die stack has four of the testing structures, one at each corner of the die as shown on FIGS. 10 and 11A-11D above. Say the pitch is 3 microns, where P/10=0.3 microns so that any error less that 0.3 microns is not detectable for this translation resolution. Now say each testing structure has a position with the upper left testing structure (here 1): (x1, y1)=(−5, 5) at center of the structure, the upper right testing structure (here 2): (x2, y2)=(5, 5) at center of structure, the lower right testing structure (here 3): (x3, y3)=(5, −5) at center of structure, and the lower left testing structure (here 4): (x4, y4)=(−5, −5) at center of structure. Also, assume all four testing structures show the same translation (Δx1, Δx2, . . . )=0.3 microns, while (Δy1, Δy2, . . . )=0.3 microns, for P/10 translations both upward (Y shift) and to the right (X shift).

Using these values from at least two different testing structures and the two equations (5) and (6), 0 equals 3.5 E-5 radians (0.002 degrees) counter-clockwise. This can be done by using a matrix as one example to search for the rotational error by including the variables from equations (5) and (6), and this can be put in a truth table with the rotational error for future use. A program can be used to make the computations. A table can be made for different rotational resolutions.

Once the rotational error is computed, the total translation plus rotation error of equations (5) and (6) can be computed for each testing structure for the example values presented above. Here, plugging into equations (5) and (6): (Δx1, Δy1)=0.13, 0.13 microns, which is too small to detect the leakage. (Δx2, Δy2)=0.13 and 0.47 microns, (Δx3, Δy3)=0.47 and 0.47 microns, while (Δx4, Δy4)=0.47 and 0.13 microns.

In this calculation, the rotational direction (clockwise or counter-clockwise) may be indicated by the positive or negative value of 0, where here positive value of 0 is counter clockwise and negative is clockwise.

To compute the rotational error angle resolution that is desired:

$$\begin{matrix}Die min size ( {D}_{min} ) = minimum of x or y die size . \\ Rotational resolution ( degrees ) = ( P / 10 {D}_{min} ) * 180 / π\end{matrix}$$

As an example calculation of rotational resolution, for a 10 mm die size and 10 micron pitch (P):

rotational resolution=0.00057 degrees

It should be noted that a rotational angle error may be determined by determining the misalignment magnitudes on all four testing structures when it occurs, and then using a look-up table to find the rotational error. Two of the testing structures may be use instead although this may not be as accurate as using more testing structures.

Thereafter, process 1700 may report the measured values to a controller, where the controller may output the magnitude and direction values external to whichever device computed the misalignment magnitude and for further analysis and adjustments to the manufacturing alignment tools, for example.

It also will be appreciated that since the testing structures can be used instead of imaging fiducials for post-bond alignment testing, any of the devices above may have fiducial regions and fiducial region columns with metallization and are completely free of KOZs due to fiducial-related purposes (KOZs may still exist for other purposes). The result is a substantially fully uniform, electrically active die without any metal free zones (for fiducial purposes herein) for best flexibility and utilization.

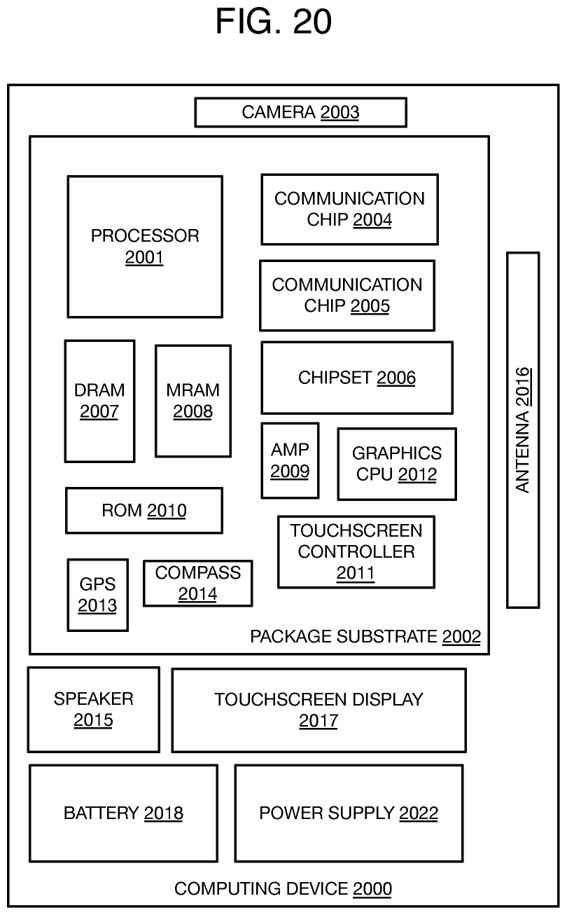

Referring to FIG. 20, a functional block diagram of an electronic computing device 2000 is in accordance with at least one of the implementations herein. Device 2000 further includes a package substrate 2002 hosting a number of components, such as, but not limited to, a processor 2001 (e.g., an applications processor). Processor 2001 may be physically and/or electrically coupled to package substrate 2002. In some examples, processor 2001 is within a composite IC chip structure including IC dies bonded to each other with post-bonding pad alignment testing structures as described elsewhere herein, and may include a chiplet bonded to a host IC chip, for example. Processor 2001 may be implemented with circuitry in any of the IC dies. In general, the term “processor” or “microprocessor” may refer to any device or portion of a device that processes electronic data from registers and/or memory to transform that electronic data into other electronic data that may be further stored in registers and/or memory.

In various examples, one or more communication chips 2004 and 2005 may also be physically and/or electrically coupled to the package substrate 2002. In further implementations, communication chips 2004 and 2005 may be part of processor 2001. Depending on its applications, computing device 2000 may include other components that may or may not be physically and electrically coupled to package substrate 2002. These other components include, but are not limited to, volatile memory (e.g., DRAM 2007), non-volatile memory (e.g., ROM 2010), flash memory (e.g., NAND or NOR), magnetic memory (MRAM 2008), a graphics processor or CPU 2012, a digital signal processor, a crypto processor, a chipset 2006, an antenna 2016, touchscreen display 2017, touchscreen controller 2011, battery 2018, power supply 2022, audio codec, video codec, power amplifier 2009, global positioning system (GPS) device 2013, compass 2014, accelerometer, gyroscope, speaker 2015, camera 2003, and mass storage device (such as hard disk drive, solid-state drive (SSD), compact disk (CD), digital versatile disk (DVD), and so forth), or the like. In some exemplary implementations, at least two of the functional blocks noted above are within a composite IC chip structure including bonded IC dies with pad alignment testing structures and/or a chiplet bonded to a host IC chip, for example as described elsewhere herein. For example, processor 2001 may be implemented with circuitry in an IC die, and an electronic memory (e.g., MRAM 2008 or DRAM 2007) may be implemented with circuitry in a second of the IC dies, including an IC chip and chiplet.

Communication chips 2004 and 2005 may enable wireless communications for the transfer of data to and from the computing device 2000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some implementations they might not. Communication chips 2004 and 2005 may implement any of a number of wireless standards or protocols. As discussed, computing device 2000 may include a plurality of communication chips 2004 and 2005. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

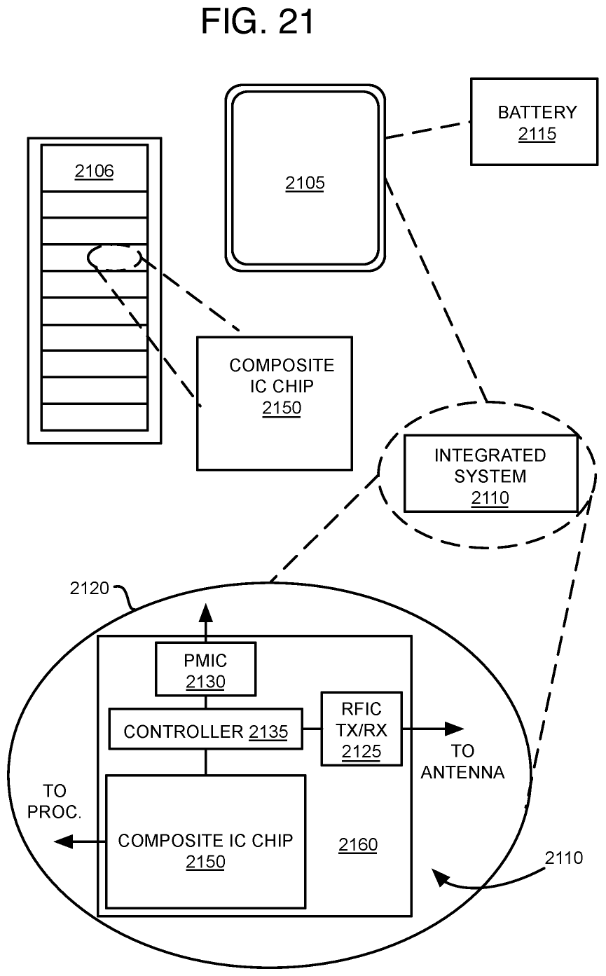

Referring to FIG. 21, a mobile computing platform 2105 and a data server machine 2106 employs an IC device comprising at least two IC die with post-bond pad alignment testing as described above. Computing device 2000 may be found inside platform 2105 or server machine 2106, for example. The server machine 2106 may be any commercial server, for example including any number of high-performance computing platforms disposed within a rack and networked together for electronic data processing, which in the exemplary implementation includes a composite IC chip 2150 that includes IC dies bonded to each other, and/or a chiplet bonded to a host IC chip, for example, and with pad alignment testing structure as described elsewhere herein. The mobile computing platform 2105 may be any portable device configured for each of electronic data display, electronic data processing, wireless electronic data transmission, or the like. For example, the mobile computing platform 2105 may be any of a tablet, a smart phone, laptop computer, etc., and may include a display screen (e.g., a capacitive, inductive, resistive, or optical touchscreen), a chip-level or package-level integrated system 2110, and a battery 2115.

Whether disposed within the integrated system 2110 illustrated in the expanded view 2120, or as a stand-alone package within the server machine 2106, composite IC chip 2150 may include IC dies bonded together and then monitored using a pad alignment testing structure described above, and may include a chiplet bonded to a host IC chip, for example. Composite IC chip 2150 may be further coupled to a host substrate 2160, along with, one or more of a power management integrated circuit (PMIC) 2130, RF (wireless) integrated circuit (RFIC) 2125 including a wideband RF (wireless) transmitter and/or receiver (TX/RX) (e.g., including a digital baseband and an analog front end module further comprises a power amplifier on a transmit path and a low noise amplifier on a receive path), and a controller 2135. PMIC 2130 may perform battery power regulation, DC-to-DC conversion, etc., and so has an input coupled to battery 2115 and with an output providing a current supply to other functional modules. As further illustrated, in the exemplary implementation, RFIC 2125 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 4G, and beyond.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

Also, it is understood that the subject matter of the present description is not necessarily limited to specific applications illustrated in FIGS. 1-21. The subject matter may be applied to other electronic devices and assembly applications, as well as any appropriate electronic application, as will be understood to those skilled in the art.

The following examples pertain to further implementations. Specifics in the examples may be used anywhere in one or more implementations.

In example 1, an integrated circuit (IC) package, comprising: a stack with first and second electronic devices respectively having a first array and a second array of rows and columns of pads bonded to each other; and at least one testing structure, comprising: a first pattern of first pads of the first array, a second pattern of second pads of the second array, and at least four pad-pairs of one of the first pads adjacent to one of the second pads, wherein each pair has different pads than the other pairs, and an aligned state of the first and second electronic devices wherein each pad-pair has a different offset length separating the first pad from the second pad, wherein at least two of the pairs are row pairs having offsets parallel to the rows of the first and second arrays and at least two other pairs are column pairs having offsets parallel to the columns of the first and second arrays, and wherein none of the first and second pads of the pairs are electrically connected.

In example 2, the subject matter of example 1, wherein the testing structure comprises a mis-aligned state of the first and second electronic devices wherein the first and second pads of at least one of the pairs is electrically connected.

In example 3, the subject matter of example 1 or 2, wherein the first and second pads in the row pairs are in a different order in each row pair, and the first and second pads in the column pairs are in a different order in each column pair, wherein each row pair is arranged to indicate misalignment in an opposite direction parallel to the rows, and wherein each column pair is arranged to indicate misalignment in an opposite direction parallel to the columns.

In example 4, the subject matter of any one of examples 1 to 3, wherein all of the offset lengths are less than half a pitch between pads of the first and second arrays external to the first and second pattern.

In example 5, the subject matter of any one of examples 1 to 4, wherein the offset lengths of the four pairs are 1/10, 2/10, 3/10, and 4/10 of a pitch between pads of the first and second arrays external to the first and second patterns.

In example 6, the subject matter of any one of examples 1 to 5, wherein the first and second pads have the same width as pads of the first and second arrays external to the first and second patterns.

In example 7, the subject matter of any one of examples 1 to 6, wherein the IC package comprises multiple testing structures spaced from each other on the first and second arrays, wherein each testing structure has a merged pattern comprising the first and second pads, and wherein a same set of offset lengths are placed at different pair positions within the merged pattern at each different testing structure of the multiple testing structures.

In example 8, the subject matter of any one of examples 1 to 7, wherein the at least one testing structure comprises a cross pattern of pads with four arms, wherein each pair of the at least one testing structure is on a different one of the arms.

In example 9, the subject matter of example 8, wherein the second pads are positioned at a different distance greater than a single pitch from a center of the cross pattern depending on the offset length, and without an intervening pad between the center of the cross pattern and the second pads, wherein the pitch is that of pads of the first or second array external to the first or second patterns.

In example 10, the subject matter of example 9, wherein the first pads are spaced from the center of the cross pattern by the pitch.

In example 11, the subject matter of example 9, wherein the first array has at least one dummy pad over or under individual second pads.

In example 12, A pad alignment testing structure of an electronic device, comprises a first die comprising a first pattern of first pads with a first array of rows and columns of the first pads; a second die over or under the first die comprising a second pattern of second pads with a second array of rows and columns of the second pads, wherein the pads of the first array are bonded to the pads of the second array; at least four pad-pairs of one of the first pads adjacent to one of the second pads, wherein each pair has different pads than the other pairs; and an aligned state of the first and second dies wherein each pad-pair has a different offset length separating the first pad from the second pad, wherein at least two of the pairs are row pairs having offsets parallel to the rows of the first and second arrays and at least two other pairs are column pairs having offsets parallel to the columns of the first and second arrays, and wherein none of the first and second pads of the pairs are electrically connected.

In example 13, the subject matter of example 12, wherein the pad alignment testing structure comprises a mis-aligned state of the first and second dies wherein the first and second pads of at least one of the pairs is electrically connected.

In example 14, the subject matter of example 12 or 13, wherein the second pads of each row pad is out of alignment with the columns of the second array, and wherein the second pads of each column pad is out of alignment with the rows of the second array, and wherein the first pads are positioned at a same pitch as pads of the first and second arrays external to the first and second patterns.

In example 15, the subject matter of any one of examples 12 to 14, wherein at least one of the first and second dies is rectangular with four corners, and wherein one of the testing structures are placed near each one of the corners, and wherein mis-aligned states indicating opposite misalignment directions at testing structures at different corners indicates a rotational misalignment.

In example 16, the subject matter of any one of examples 12 to 15, wherein the first and second dies have multiple testing structures all having the same offset lengths, wherein the offset lengths are at a different pair position at each testing structure.

In example 17, an electronic system, comprises a package substrate and a stack with first and second electronic devices each being a die or a wafer over or under the substrate, and each having a first array and a second array of rows and columns respectively of first and second pads bonded to each other; and at least one testing structure comprising: a first pattern of first pads of the first array, a second pattern of second pads of the second array, and at least four pad-pairs of one of the first pads adjacent to one of the second pads, wherein each pair has different pads than the other pairs, an aligned state and a mis-aligned state of the first and second electronic devices, wherein in the aligned state each pad-pair has a different offset length separating the first pad from the second pad, wherein at least two of the pairs are row pairs having offsets parallel to the rows of the first and second arrays and at least two other pairs are column pairs having offsets parallel to the columns of the first and second arrays, and wherein none of the first and second pads of the pairs are electrically connected.

In example 18, the subject matter of example 17, wherein in the a mis-aligned state, the first and second pads of at least one of the pairs is electrically connected.

In example 19, the subject matter of example 17 or 18, wherein the first electronic device comprises at least two features with conductive material and exposed at an outer surface of the first electronic device and electrically coupled to the first pads; and wherein the system comprises test circuitry coupled to the at least two features and a current source.

In example 20, the subject matter of any one of examples 17 to 19, the system comprising ground circuitry on the second electronic device and coupled to the second pads.

In example 21, a device, apparatus, or system includes means to perform a method according to any one of the above implementations.

In example 22, at least one machine readable medium includes a plurality of instructions that in response to being executed on a computing device, cause the computing device to perform a method according to any one of the above implementations.

It will be recognized that the disclosures herein are not limited to the implementations so described, but can be practiced with modification and alteration without departing from the scope of the appended claims. For example, the above implementations may include specific combination of features. However, the above implementations are not limited in this regard and, in various implementations, the above implementations may include undertaking only a subset of such features, undertaking a different order of such features, undertaking a different combination of such features, and/or undertaking additional features than those features explicitly listed. The scope of the assemblies, devices, and methods disclosed herein should, therefore, be determined with reference to the appended claims, along with the full scope of equivalents to which such claims are entitled.

What is claimed is:

1. An integrated circuit (IC) package, comprising:
a stack with first and second electronic devices respectively having a first array and a second array of rows and columns of pads bonded to each other; and
at least one testing structure, comprising:
a first pattern of first pads of the first array, a second pattern of second pads of the second array, and at least four pad-pairs of one of the first pads adjacent to one of the second pads, wherein each pair has different pads than the other pairs, and
an aligned state of the first and second electronic devices wherein each pad-pair has a different offset length separating the first pad from the second pad, wherein at least two of the pairs are row pairs having offsets parallel to the rows of the first and second arrays and at least two other pairs are column pairs having offsets parallel to the columns of the first and second arrays, and wherein none of the first and second pads of the pairs are electrically connected.

2. The IC package of claim 1, wherein the testing structure comprises a mis-aligned state of the first and second electronic devices wherein the first and second pads of at least one of the pairs is electrically connected.

3. The IC package of claim 1, wherein the first and second pads in the row pairs are in a different order in each row pair, and the first and second pads in the column pairs are in a different order in each column pair, wherein each row pair is arranged to indicate misalignment in an opposite direction parallel to the rows, and wherein each column pair is arranged to indicate misalignment in an opposite direction parallel to the columns.

4. The IC package of claim 1, wherein all of the offset lengths are less than half a pitch between pads of the first and second arrays external to the first and second pattern.

5. The IC package of claim 1, wherein the offset lengths of the four pairs are 1/10, 2/10, 3/10, and 4/10 of a pitch between pads of the first and second arrays external to the first and second patterns.

6. The IC package of claim 1, wherein the first and second pads have the same width as pads of the first and second arrays external to the first and second patterns.

7. The IC package of claim 1, comprising multiple testing structures spaced from each other on the first and second arrays, wherein each testing structure has a merged pattern comprising the first and second pads, and wherein a same set of offset lengths are placed at different pair positions within the merged pattern at each different testing structure of the multiple testing structures.

8. The IC package of claim 1, wherein the at least one testing structure comprises a cross pattern of pads with four arms, wherein each pair of the at least one testing structure is on a different one of the arms.

9. The IC package of claim 8, wherein the second pads are positioned at a different distance greater than a single pitch from a center of the cross pattern depending on the offset length, and without an intervening pad between the center of the cross pattern and the second pads, wherein the pitch is that of pads of the first or second array external to the first or second patterns.

10. The IC package of claim 9, wherein the first pads are spaced from the center of the cross pattern by the pitch.

11. The IC package of claim 9, wherein the first array has at least one dummy pad over or under individual second pads.

12. A pad alignment testing structure of an electronic device, comprising:
a first die comprising a first pattern of first pads with a first array of rows and columns of the first pads;
a second die over or under the first die comprising a second pattern of second pads with a second array of rows and columns of the second pads, wherein the pads of the first array are bonded to the pads of the second array;
at least four pad-pairs of one of the first pads adjacent to one of the second pads, wherein each pair has different pads than the other pairs; and
an aligned state of the first and second dies wherein each pad-pair has a different offset length separating the first pad from the second pad, wherein at least two of the pairs are row pairs having offsets parallel to the rows of the first and second arrays and at least two other pairs are column pairs having offsets parallel to the columns of the first and second arrays, and wherein none of the first and second pads of the pairs are electrically connected.

13. The pad alignment testing structure of claim 12, comprising a mis-aligned state of the first and second dies wherein the first and second pads of at least one of the pairs is electrically connected.

14. The pad alignment testing structure of claim 12, wherein the second pads of each row pad is out of alignment with the columns of the second array, and wherein the second pads of each column pad is out of alignment with the rows of the second array, and wherein the first pads are positioned at a same pitch as pads of the first and second arrays external to the first and second patterns.

15. The pad alignment testing structure of claim 12, wherein at least one of the first and second dies is rectangular with four corners, and wherein one of the testing structures are placed near each one of the corners, and wherein mis-aligned states indicating opposite misalignment directions at testing structures at different corners indicates a rotational misalignment.

16. The pad alignment testing structure of claim 12, wherein the first and second dies have multiple testing structures all having the same offset lengths, wherein the offset lengths are at a different pair position at each testing structure.

17. An electronic system, comprising:
a package substrate and a stack with first and second electronic devices each being a die or a wafer over or under the substrate, and each having a first array and a second array of rows and columns respectively of first and second pads bonded to each other; and
at least one testing structure comprising:
a first pattern of first pads of the first array, a second pattern of second pads of the second array, and at least four pad-pairs of one of the first pads adjacent to one of the second pads, wherein each pair has different pads than the other pairs,
an aligned state and a mis-aligned state of the first and second electronic devices, wherein in the aligned state each pad-pair has a different offset length separating the first pad from the second pad, wherein at least two of the pairs are row pairs having offsets parallel to the rows of the first and second arrays and at least two other pairs are column pairs having offsets parallel to the columns of the first and second arrays, and wherein none of the first and second pads of the pairs are electrically connected.

18. The system of claim 17, wherein in the a mis-aligned state, the first and second pads of at least one of the pairs is electrically connected.

19. The system of claim 17, wherein the first electronic device comprises at least two features with conductive material and exposed at an outer surface of the first electronic device and electrically coupled to the first pads; and wherein the system comprises test circuitry coupled to the at least two features and a current source.

20. The system of claim 17, comprising ground circuitry on the second electronic device and coupled to the second pads.
